(19) United States
(12) Patent Application Publication
(10) Pub. No.: US 2025/0015020 A1
(43) Pub. Date: Jan. 9, 2025

(54) IC CHIP, RADIO FREQUENCY MODULE, AND COMMUNICATION DEVICE

(71) Applicant: Murata Manufacturing Co., Ltd., Kyoto (JP)

(72) Inventor: Atsushi ONO, Kyoto (JP)

(21) Appl. No.: 18/887,369

(22) Filed: Sep. 17, 2024

Related U.S. Application Data
(63) Continuation of application No. PCT/JP2023/010597, filed on Mar. 17, 2023.

(30) Foreign Application Priority Data
Mar. 18, 2022 (JP) 2022-044702

(51) Int. Cl. H01L 23/66; H01L 23/00; H01L 25/065; H01L 25/10

(52) U.S. Cl. CPC H01L 23/66; H01L 24/14; H01L 24/16; H01L 25/0655; H01L 25/105; H01L 2223/6644; H01L 2223/6677; H01L 2224/14515; H01L 2224/16225; H01L 2225/107; H01L 2924/14215

(57) ABSTRACT

In an IC chip, a control unit is connected to at least one of a first switch unit and a second switch unit. In plan view from a thickness direction of a substrate, a plurality of first terminals are located between the first switch unit and the second switch unit in a first direction, and are arranged in a line in a second direction intersecting with the first direction. In plan view from the thickness direction of the substrate, a plurality of second terminals are located between the plurality of first terminals, and the first switch unit or the second switch unit, and are arranged in a line in the second direction. The plurality of first terminals include at least one control terminal among a plurality of control terminals connected to the control unit. The plurality of second terminals include a ground terminal.

### CROSS REFERENCE TO RELATED APPLICATION

This is a continuation of International Application No. PCT/JP2023/010597 filed on Mar. 17, 2023 which claims priority from Japanese Patent Application No. 2022-044702 filed on Mar. 18, 2022. The contents of these applications are incorporated herein by reference in their entireties.

### BACKGROUND OF THE DISCLOSURE

### Field of the Disclosure

The present disclosure generally relates to an IC chip, a radio frequency module, and a communication device, and more particularly relates to an IC chip including a plurality of switch units, a radio frequency module including the IC chip, and a communication device including the radio frequency module.

### Description of the Related Art

Patent Document 1 discloses a front-end module including a switch IC (IC chip). The switch IC includes a first switch unit and a third switch unit, and the first switch unit and the third switch unit are disposed to be adjacent to each other. The first switch unit includes an input terminal and an output terminal. In the first switch unit, the input terminal is connected to an antenna element.

The switch IC includes a base (substrate). In top view of the base, the first switch unit and the third switch unit are disposed to be adjacent to each other.

In the switch IC, the connection of each of a plurality of switches constituting the first switch unit and the connection of each of a plurality of switches constituting the third switch unit are switched by a control unit provided in the front-end module.

Patent Document 1: PCT International Publication No. WO2018/110393

### BRIEF SUMMARY OF THE DISCLOSURE

In an IC chip including a plurality of switch units including a switch unit connected to an antenna terminal, the isolation between switch units different from each other may be decreased.

A possible benefit of the present disclosure is to provide an IC chip, a radio frequency module, and a communication device capable of improving the isolation between switch units different from each other.

According to an aspect of the present disclosure, an IC chip includes a substrate, a first switch unit, a second switch unit, a control unit, a plurality of first terminals, and a plurality of second terminals. The first switch unit is formed at the substrate. The first switch unit includes a first common terminal connected to an antenna terminal and a plurality of first selection terminals that are connectable to the first common terminal. The second switch unit is formed at the substrate. The second switch unit includes a second common terminal connected to a transmission path and a plurality of second selection terminals that are connectable to the second common terminal. The control unit is formed at the substrate. The control unit is connected to at least one of the first switch unit and the second switch unit. In plan view from a thickness direction of the substrate, the plurality of first terminals are located between the first switch unit and the second switch unit in a first direction and are arranged in a line in a second direction intersecting with the first direction. In plan view from the thickness direction of the substrate, the plurality of second terminals are located between the plurality of first terminals, and the first switch unit or the second switch unit and are arranged in a line in the second direction. The plurality of first terminals include at least one control terminal among a plurality of control terminals connected to the control unit. The plurality of second terminals include a ground terminal.

According to an aspect of the present disclosure, a radio frequency module includes the IC chip in the above aspect and a mounting board on which the IC chip is disposed.

According to an aspect of the present disclosure, a communication device includes the radio frequency module according to the above aspect, and a signal processing circuit. The signal processing circuit is connected to the radio frequency module.

The IC chip, the radio frequency module, and the communication device according to the aspects of the present disclosure can improve the isolation between switch units different from each other.

### BRIEF DESCRIPTION OF THE SEVERAL VIEWS OF THE DRAWINGS

FIG. 1 is a plan view for describing a layout of an IC chip according to Embodiment 1.

FIG. 2 is a sectional view of the IC chip taken along line X1-X1 in FIG. 1.

FIG. 3 is a plan view for describing a layout of a plurality of first terminals and a plurality of second terminals in the IC chip.

FIG. 4 is a plan view for describing the layout of the plurality of first terminals and the plurality of second terminals in the IC chip.

FIG. 5 is a plan view of a radio frequency module according to Embodiment 1.

FIG. 6 is a plan view viewed transparently from a first main surface side to a second main surface side of a mounting board, relating to the radio frequency module.

FIG. 7 is another plan view of the radio frequency module.

FIG. 8 is a sectional view of the radio frequency module taken along line X2-X2 in FIG. 7.

FIG. 9 is a circuit block diagram of a communication device including the radio frequency module.

FIG. 10 is a plan view for describing a layout of an IC chip according to Modification Example 1 of Embodiment 1.

FIG. 11 is a plan view for describing a layout of an IC chip according to Modification Example 2 of Embodiment 1.

FIG. 12 is a plan view for describing a layout of an IC chip according to Modification Example 3 of Embodiment 1.

FIG. 13 is a plan view for describing a layout of an IC chip according to Embodiment 2.

### DETAILED DESCRIPTION OF THE DISCLOSURE

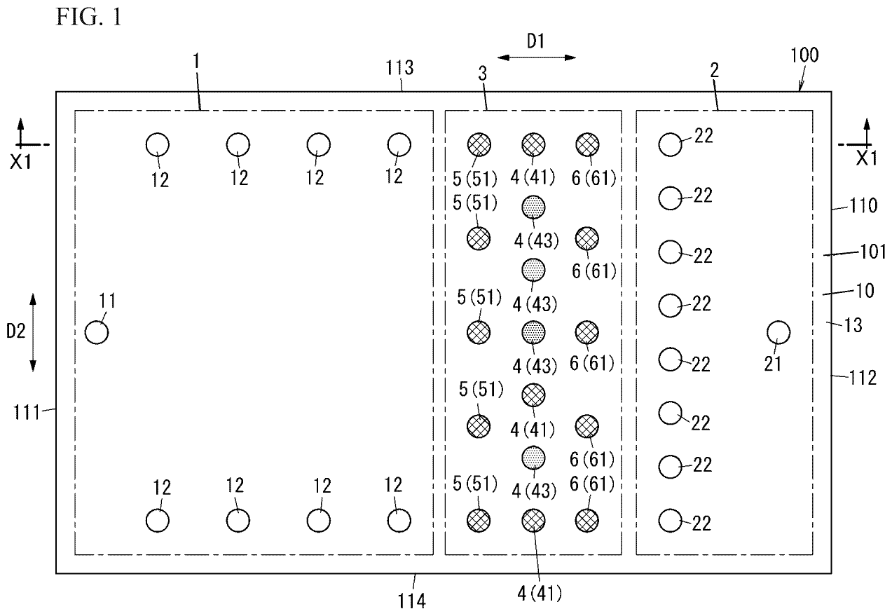

FIGS. 1 to 8 and 10 to 13, which are referred to in the following embodiments or the like, are all schematic views, and each of ratios of sizes or thicknesses of each constituent element in the drawing does not necessarily reflect the actual dimensional ratio.

### Embodiment 1

### (1) Outline

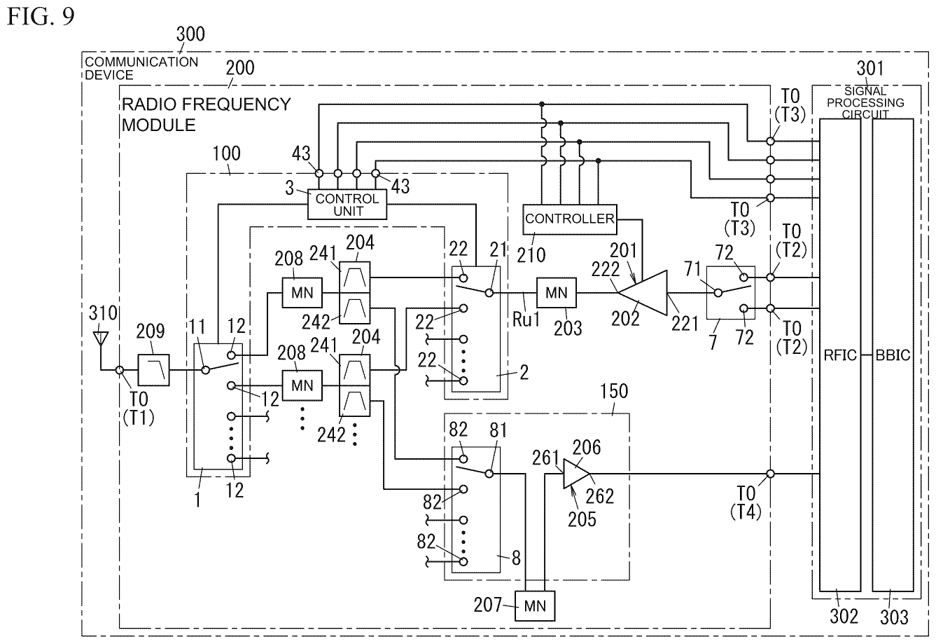

For example, as shown in FIG. 9, an IC chip 100 is used in a radio frequency module 200. The “radio frequency module” as used in the present specification is a module used in communication of radio frequency signals. The radio frequency module 200 is used, for example, in a communication device 300 as shown in FIG. 9. The communication device 300 is, for example, a mobile phone (for example, a smartphone), but the present disclosure is not limited thereto, and may be, for example, a wearable terminal (for example, a smartwatch), or the like. The radio frequency module 200 is, for example, a module capable of supporting the fourth generation mobile communication (4G) standard, the fifth generation mobile communication (5G) standard, and the like. For example, the 4G standard is the third generation partnership project (3GPP: registered trademark) long term evolution (LTE: registered trademark) standard. The 5G standard is, for example, 5G new radio (NR). The radio frequency module 200 is, for example, a module capable of supporting carrier aggregation and dual connectivity.

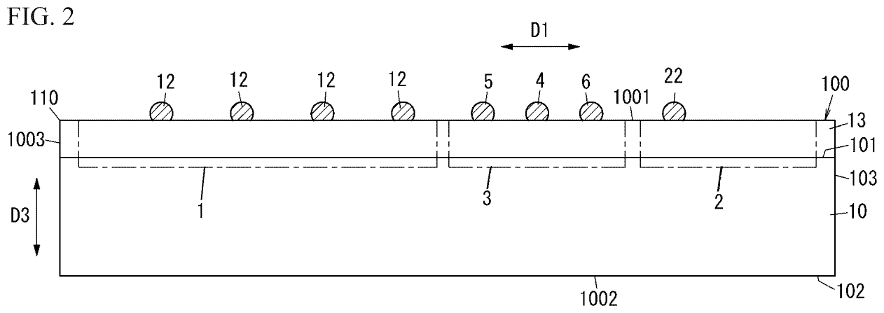

As shown in FIGS. 1 and 2, the IC chip 100 includes a substrate 10, a first switch unit 1, a second switch unit 2, a control unit 3, a plurality (for example, seven) of first terminals 4, and a plurality (for example, five) of second terminals 5. The first switch unit 1 is formed at the substrate 10. The first switch unit 1 includes a first common terminal 11 connected to an antenna terminal T1 (see FIG. 9) and a plurality (for example, eight) of first selection terminals 12 that are connectable to the first common terminal 11. The second switch unit 2 is formed at the substrate 10. The second switch unit 2 includes a second common terminal 21 connected to a transmission path Ru1 and a plurality (for example, eight) of second selection terminals 22 that are connectable to the second common terminal 21. The control unit 3 is formed at the substrate 10. The control unit 3 is connected to the first switch unit 1 and the second switch unit 2. In plan view from a thickness direction D3 of the substrate 10, the plurality of first terminals 4 are located between the first switch unit 1 and the second switch unit 2 in a first direction D1 and are arranged in a line in a second direction D2 intersecting with the first direction D1. For example, the second direction D2 is a direction perpendicular to the first direction D1. In plan view from the thickness direction D3 of the substrate 10, the plurality of second terminals 5 are located between the plurality of first terminals 4 and the first switch unit 1 and are arranged in a line in the second direction D2. The plurality of first terminals 4 are connected to the control unit 3. The plurality of first terminals 4 include at least one control terminal 43 among a plurality (for example, four) of control terminals 43. The plurality of second terminals 5 include a ground terminal 51.

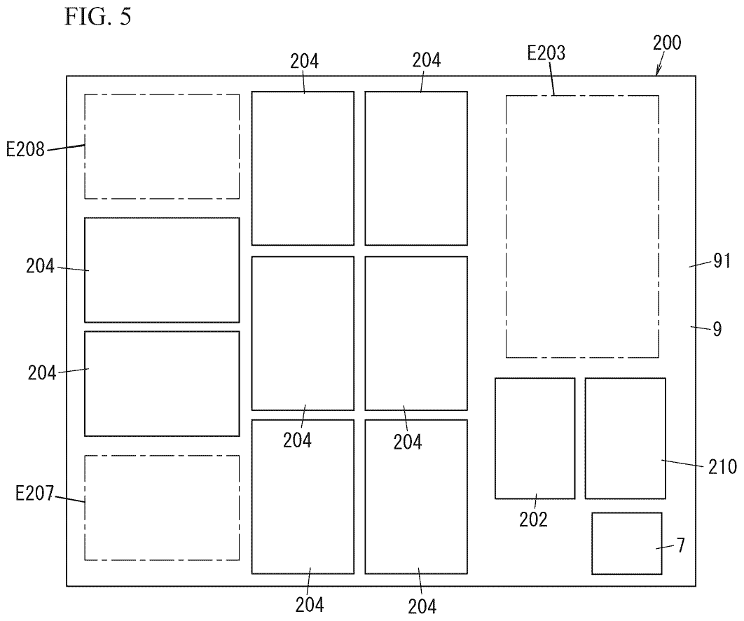

The radio frequency module 200 according to Embodiment 1 includes a mounting board 9 and the IC chip 100 as shown in FIGS. 5 to 8. The IC chip 100 is disposed on the mounting board 9.

As shown in FIG. 9, the radio frequency module 200 further includes a transmission circuit 201. The transmission circuit 201 includes a power amplifier 202. In addition, the radio frequency module 200 further includes a reception circuit 205. The reception circuit 205 includes a low-noise amplifier 206. In addition, the radio frequency module 200 further includes a plurality (for example, eight) of duplexers 204. Each of the plurality of duplexers 204 includes a transmission filter 241 and a reception filter 242. As a result, the radio frequency module 200 includes a plurality (for example, eight) of transmission filters 241 having pass bands different from each other, and a plurality (for example, eight) of reception filters 242 having pass bands different from each other. In the radio frequency module 200, the plurality of transmission filters 241 and the plurality of reception filters 242 are in one-to-one correspondence, and the plurality of transmission filters 241 and the plurality of reception filters 242 correspond to, for example, a plurality of communication bands. Each of the plurality of communication bands is, for example, a communication band used for communication corresponding to frequency division duplex (FDD) as a communication method, a communication band used for communication corresponding to time division duplex (TDD) as a communication method, or a communication band used for communication corresponding to supplemental downlink (SDL) as a communication method. The plurality of communication bands include, for example, two or more communication bands included in a combination of communication bands allowed for simultaneous communication. The phrase of being allowed for simultaneous communication means that at least one of simultaneous reception, simultaneous transmission, and simultaneous transmission and reception is possible.

As shown in FIG. 9, the communication device 300 includes the radio frequency module 200 and a signal processing circuit 301. The communication device 300 further includes an antenna 310. The communication device 300 further includes a circuit board (not shown) at which the radio frequency module 200 is mounted. The circuit board is, for example, a printed wiring board. The circuit board includes a ground electrode to which a ground potential is applied.

### (2) Details

The circuit configurations of the radio frequency module 200 and the communication device 300 will be described below, and then the structures of the IC chip 100 and the radio frequency module 200 will be described in more detail.

### (2.1) Circuit Configuration of Radio Frequency Module

The circuit configuration of the radio frequency module 200 according to Embodiment 1 will be described with reference to FIG. 9.

The radio frequency module 200 is configured, for example, to be able to amplify a reception signal received from the antenna 310 and output the amplified reception signal to the signal processing circuit 301. In addition, the radio frequency module 200 is configured to, for example, be able to amplify a transmission signal received from the signal processing circuit 301 and output the amplified transmission signal to the antenna 310. The signal processing circuit 301 is not a constituent element of the radio frequency module 200, but a constituent element of the communication device 300 including the radio frequency module 200. The radio frequency module 200 is controlled by, for example, the signal processing circuit 301 of the communication device 300.

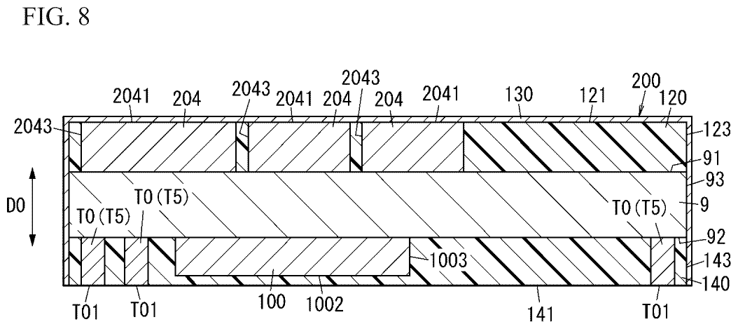

As shown in FIG. 9, the radio frequency module 200 includes the first switch unit 1, the second switch unit 2, and the control unit 3. In addition, the radio frequency module 200 includes a third switch unit 7, a fourth switch unit 8, the plurality (for example, eight) of duplexers 204, the transmission circuit 201, the reception circuit 205, and a plurality of external connection terminals T0. The plurality of external connection terminals T0 include the antenna terminal T1, a plurality (for example, two) of signal input terminals T2, a plurality (for example, four) of external control terminals T3, a signal output terminal T4, and a plurality of external ground terminals T5 (see FIG. 8). In addition, the radio frequency module 200 includes a controller 210, a low pass filter 209, and a plurality (for example, eight) of matching circuits 208.

The first switch unit 1 includes the first common terminal 11 and the plurality (for example, eight) of first selection terminals 12 that are connectable to the first common terminal 11. The first common terminal 11 of the first switch unit 1 is connected to the antenna terminal T1. More specifically, the first common terminal 11 of the first switch unit 1 is connected to the antenna terminal T1, for example, through the low pass filter 209. The plurality of first selection terminals 12 of the first switch unit 1 are connected to the plurality of duplexers 204. Each of the plurality of first selection terminals 12 is connected to the corresponding duplexer 204 among the plurality of duplexers 204. More specifically, each of the plurality of first selection terminals 12 of the first switch unit 1 is connected to the transmission filter 241 and the reception filter 242 of the corresponding duplexer 204 among the plurality of duplexers 204 through the matching circuit 208.

The first switch unit 1 includes, for example, a first switch circuit capable of connecting one or more first selection terminals 12 among the plurality of first selection terminals 12 to the first common terminal 11. Here, the first switch unit 1 is capable of connecting the first common terminal 11 and the plurality of first selection terminals 12 in a one-to-one manner and a one-to-many manner, for example. The first switch unit 1 is controlled by the control unit 3. The first switch unit 1 switches the connection state between the first common terminal 11 and the plurality of first selection terminals 12 under the control of the control unit 3. The first switch unit 1 can switch the connection relationship between the antenna 310 and the plurality of duplexers 204. Thus, the first switch unit 1 can switch the connection relationship between the antenna 310 and the plurality of transmission filters 241, and can switch the connection relationship between the antenna 310 and the plurality of reception filters 242.

The second switch unit 2 includes the second common terminal 21 and the plurality (for example, eight) of second selection terminals 22 that are connectable to the second common terminal 21. The second common terminal 21 of the second switch unit 2 is connected to an output terminal 222 of the power amplifier 202 included in the transmission circuit 201. More specifically, the second common terminal 21 of the second switch unit 2 is connected to the output terminal 222 of the power amplifier 202, for example, through an output matching circuit 203. The plurality of second selection terminals 22 of the second switch unit 2 are connected to the plurality of transmission filters 241. Each of the plurality of second selection terminals 22 is connected to the corresponding transmission filter 241 among the plurality of transmission filters 241.

The second switch unit 2 includes, for example, a second switch circuit capable of connecting one or more second selection terminals 22 among the plurality of second selection terminals 22 to the second common terminal 21. Here, the second switch unit 2 is capable of connecting the second common terminal 21 and the plurality of second selection terminals 22 in a one-to-one manner and a one-to-many manner, for example. The second switch unit 2 is controlled by the control unit 3. The second switch unit 2 switches the connection state between the second common terminal 21 and the plurality of second selection terminals 22 under the control of the control unit 3.

The control unit 3 controls, for example, the first switch unit 1 and the second switch unit 2 in accordance with a control signal from the signal processing circuit 301. The control signal outputted from the signal processing circuit 301 is a digital control signal. The control signals from the signal processing circuit 301 are inputted to the plurality of external control terminals T3 of the radio frequency module 200, are inputted to the plurality of control terminals 43 connected to the plurality of external control terminals T3, and are inputted to the control unit 3 connected to the plurality of control terminals 43.

The third switch unit 7 includes a third common terminal 71 and a plurality (for example, two) of third selection terminals 72 that are connectable to the third common terminal 71. The third common terminal 71 of the third switch unit 7 is connected to an input terminal 221 of the power amplifier 202 included in the transmission circuit 201. The plurality of third selection terminals 72 of the third switch unit 7 are connected to the plurality of signal input terminals T2. Each of the plurality of third selection terminals 72 is connected to the corresponding signal input terminal T2 among the plurality of signal input terminals T2.

The third switch unit 7 includes, for example, a third switch circuit that switches the connection state between the third common terminal 71 and the plurality of third selection terminals 72. Here, the third switch unit 7 is controlled by, for example, the controller 210. The third switch unit 7 switches the connection state between the third common terminal 71 and the plurality of third selection terminals 72 in accordance with a control signal from the controller 210. The third switch unit 7 is, for example, a switch integrated circuit (IC).

The fourth switch unit 8 includes a fourth common terminal 81 and a plurality (for example, eight) of fourth selection terminals 82 that are connectable to the fourth common terminal 81. The fourth common terminal 81 of the fourth switch unit 8 is connected to an input terminal 261 of the low-noise amplifier 206 included in the reception circuit 205. More specifically, the fourth common terminal 81 of the fourth switch unit 8 is connected to the input terminal 261 of the low-noise amplifier 206 through, for example, an input matching circuit 207. The plurality of fourth selection terminals 82 of the fourth switch unit 8 are connected to the plurality of reception filters 242. Each of the plurality of fourth selection terminals 82 is connected to the corresponding reception filter 242 among the plurality of reception filters 242.

The fourth switch unit 8 includes, for example, a fourth switch circuit capable of connecting one or more fourth selection terminals 82 among the plurality of fourth selection terminals 82 to the fourth common terminal 81. Here, the fourth switch unit 8 is capable of connecting the fourth common terminal 81 and the plurality of fourth selection terminals 82 in a one-to-one manner and a one-to-many manner, for example. The fourth switch unit 8 is controlled by, for example, the controller 210. The fourth switch unit 8 switches the connection state between the fourth common terminal 81 and the plurality of fourth selection terminals 82 in accordance with the control signal from the controller 210. The fourth switch unit 8 is, for example, a switch IC.

Each of the plurality of duplexers 204 includes the transmission filter 241 and the reception filter 242. In each of the plurality of duplexers 204, the pass band of the transmission filter 241 is different from the pass band of the reception filter 242, but the communication band corresponding to the pass band of the transmission filter 241 is the same as the communication band corresponding to the pass band of the reception filter 242.

The transmission circuit 201 includes the power amplifier 202 and the output matching circuit 203.

The power amplifier 202 has the input terminal 221 and the output terminal 222. The power amplifier 202 performs power amplification of a transmission signal inputted to the input terminal 221 and outputs the power-amplified transmission signal from the output terminal 222. The input terminal 221 of the power amplifier 202 is connected to one of the two signal input terminals T2 through the third switch unit 7. Thus, in the communication device 300 including the radio frequency module 200, the input terminal 221 of the power amplifier 202 is connected to the signal processing circuit 301 of the communication device 300 through the third switch unit 7 and one of the two signal input terminals T2. The two signal input terminals T2 are terminals for inputting radio frequency signals (transmission signal) from an external circuit (for example, the signal processing circuit 301) to the radio frequency module 200.

The output terminal 222 of the power amplifier 202 is connected to the second common terminal 21 of the second switch unit 2 through the output matching circuit 203. Thus, the output terminal 222 of the power amplifier 202 is connectable to a plurality (for example, eight) of transmission filters 241 through the output matching circuit 203 and the second switch unit 2. The power amplifier 202 is, for example, a multi-stage amplifier including a driver stage amplifier and a final stage amplifier. The power amplifier 202 is not limited to the multi-stage amplifier and may be, for example, an in-phase combining amplifier, a differential combining amplifier, or a Doherty amplifier.

The output matching circuit 203 is provided in a signal path between the output terminal 222 of the power amplifier 202 and the second switch unit 2. The signal path between the output terminal 222 of the power amplifier 202 and the second switch unit 2 is a part of the transmission path Ru1. The output matching circuit 203 is a circuit for performing the impedance matching between the power amplifier 202 and the plurality of duplexers 204, and includes, for example, a plurality of inductors and a plurality of capacitors.

The reception circuit 205 includes the low-noise amplifier 206 and the input matching circuit 207.

The low-noise amplifier 206 has the input terminal 261 and an output terminal 262. The low-noise amplifier 206 amplifies a reception signal inputted to the input terminal 261 and outputs the amplified reception signal from the output terminal 262. The output terminal 262 of the low-noise amplifier 206 is connected to the signal output terminal T4. The output terminal 262 of the low-noise amplifier 206 is connected to the signal processing circuit 301, for example, through the signal output terminal T4. The signal output terminal T4 is a terminal for outputting a radio frequency signal (reception signal) from the low-noise amplifier 206 to an external circuit (for example, the signal processing circuit 301).

The input matching circuit 207 is provided in a signal path between the fourth switch unit 8 and the input terminal 261 of the low-noise amplifier 206. The input matching circuit 207 is a circuit for performing the impedance matching between the plurality of reception filters 242 and the low-noise amplifier 206, and includes, for example, one inductor. The input matching circuit 207 is not limited to a case of including one inductor, and may include, for example, a plurality of inductors and a plurality of capacitors.

The controller 210 controls the power amplifier 202. The controller 210 controls the power amplifier 202 in accordance with, for example, a control signal from the signal processing circuit 301. The controller 210 is connected to the signal processing circuit 301 through a plurality of (for example, four) external control terminals T3. The controller 210 controls the power amplifier 202 based on a control signal acquired from the signal processing circuit 301 through the plurality of external control terminals T3. The control signal acquired by the controller 210 is a digital control signal. In addition, the controller 210 also controls the third switch unit 7 and the fourth switch unit 8 in accordance with the control signal from the signal processing circuit 301.

The low pass filter 209 is connected between the antenna terminal T1 and the first common terminal 11 of the first switch unit 1.

The plurality (for example, eight) of matching circuits 208 are connected between the plurality of first selection terminals 12 of the first switch unit 1 and the plurality of duplexers 204. The plurality of matching circuits 208 are circuits for performing the impedance matching between the plurality of duplexers 204 and the first switch unit 1, and include, for example, a plurality of inductors and a plurality of capacitors.

The plurality of external connection terminals T0 include the antenna terminal T1, the two signal input terminals T2, the four external control terminals T3, the signal output terminal T4, and the plurality of external ground terminals T5 (see FIG. 8). The signal output terminal T4 is a terminal for outputting a radio frequency signal (reception signal) from the reception circuit 205 to an external circuit (for example, the signal processing circuit 301). The two signal input terminals T2 are terminals for inputting radio frequency signals (transmission signal) from an external circuit (for example, the signal processing circuit 301) to the radio frequency module 200. The plurality of external control terminals T3 are terminals for inputting control signals (digital control signals) from an external circuit (for example, the signal processing circuit 301) to the radio frequency module 200. That is, the plurality of external control terminals T3 function as an interface for inputting control signals from the signal processing circuit 301 to the radio frequency module 200. The plurality of external ground terminals T5 are terminals to which a ground potential is applied.

### (2.2) Circuit Configuration of Communication Device

As shown in FIG. 9, the communication device 300 includes the radio frequency module 200 and the signal processing circuit 301. The signal processing circuit 301 is connected to the radio frequency module 200. The communication device 300 further includes the antenna 310. The communication device 300 further includes a circuit board at which the radio frequency module 200 is mounted. The circuit board is, for example, a printed wiring board. The circuit board includes a ground electrode to which a ground potential is applied.

The signal processing circuit 301 includes, for example, an RF signal processing circuit 302 and a baseband signal processing circuit 303. The RF signal processing circuit 302 is, for example, a radio frequency integrated circuit (RFIC) and performs signal processing on a radio frequency signal. The RF signal processing circuit 302 performs signal processing, such as up-conversion, on the radio frequency signal (transmission signal) outputted from the baseband signal processing circuit 303, and outputs the radio frequency signal on which the signal processing is performed. In addition, the RF signal processing circuit 302 performs signal processing such as down-conversion, on a radio frequency signal (reception signal) outputted from the radio frequency module 200, and outputs the radio frequency signal on which the signal processing is performed, to the baseband signal processing circuit 303. The baseband signal processing circuit 303 is, for example, a baseband integrated circuit (BBIC). The baseband signal processing circuit 303 generates an I-phase signal and a Q-phase signal from the baseband signal. The baseband signal is, for example, an audio signal, an image signal, and the like received from the outside. The baseband signal processing circuit 303 performs IQ modulation processing by combining the I-phase signal and the Q-phase signal, and outputs a transmission signal. In this case, the transmission signal is generated as a modulation signal (IQ signal) by amplitude modulation of a carrier wave signal of a predetermined frequency in a period longer than a period of the carrier wave signal. The reception signal processed by the baseband signal processing circuit 303 is used, for example, as an image signal for image display or as an audio signal for a call by the user of the communication device 300. The radio frequency module 200 transmits the radio frequency signal (reception signal and transmission signal) between the antenna 310 and the RF signal processing circuit 302 of the signal processing circuit 301.

### (2.3) Structure of IC Chip

As shown in FIGS. 1 and 2, the IC chip 100 includes the substrate 10, a multilayer structural portion 13 formed on the substrate 10, and a plurality (for example, 35) of external terminals.

In the IC chip 100, in plan view from the thickness direction D3 of the substrate 10, an outer edge 110 of the IC chip 100 has a quadrangular shape. The outer edge 110 of the IC chip 100 includes a first side 111 and a second side 112 that face each other, and a third side 113 and a fourth side 114 that face each other. More specifically, the outer edge 110 of the IC chip 100 has a rectangular shape, each of the first side 111 and the second side 112 is a short side, and each of the third side 113 and the fourth side 114 is a long side.

The substrate 10 has a main surface 101. As shown in FIG. 2, the substrate 10 has the main surface 101 (also referred to as a first main surface 101 below) and a second main surface 102 that face each other in the thickness direction D3 of the substrate 10. In addition, the substrate 10 has an outer peripheral surface 103. The outer peripheral surface 103 of the substrate 10 includes, for example, four side surfaces that connect an outer edge of the first main surface 101 and an outer edge of the second main surface 102 of the substrate 10 to each other, and does not include the first main surface 101 or the second main surface 102. The first main surface 101 and the second main surface 102 of the substrate 10 are perpendicular to the thickness direction D3 of the substrate 10. Here, the term “perpendicular” is not limited to a case where it is strictly perpendicular (a case where an angle formed by the thickness direction D3 of the substrate 10, and the first main surface 101 or the second main surface 102 of the substrate 10 is 90°), and the angle formed by the thickness direction D3 of the substrate 10, and the first main surface 101 or the second main surface 102 of the substrate 10 only needs to be within a range of 85° or more and 95° or less. In the IC chip 100, the second main surface 102 of the substrate 10 constitutes a main surface 1002 of the IC chip 100 on a side opposite from the mounting board 9, and the outer peripheral surface 103 of the substrate 10 constitutes a part of an outer peripheral surface 1003 of the IC chip 100. The outer peripheral surface 1003 of the IC chip 100 does not include the main surface 1002 of the IC chip 100 on the side opposite from the mounting board 9 or the main surface 1001 of the IC chip 100 on the mounting board 9 side.

The substrate 10 is, for example, a semiconductor substrate. The semiconductor substrate is, for example, a silicon substrate. The semiconductor substrate is not limited to a silicon substrate and may be a silicon-on-insulator (SOI) substrate. In addition, the semiconductor substrate is not limited to a silicon substrate and may be a compound semiconductor substrate (for example, a GaAs substrate or an SiC substrate).

The multilayer structural portion 13 is formed on the first main surface 101 of the substrate 10. The multilayer structural portion 13 includes, for example, a plurality of wiring layers (not shown), an interlayer insulating film (not shown), and a passivation film (not shown). The plurality of wiring layers are formed in a predetermined pattern determined for each layer. Each of the plurality of wiring layers includes one or a plurality of wiring portions in a plane perpendicular to the thickness direction D3 of the substrate 10. FIG. 2 is a sectional view taken along line X1-X1 of FIG. 1, and the hatching of each of the substrate 10 and the multilayer structural portion 13 is omitted.

The first switch unit 1, the second switch unit 2, and the control unit 3 are formed at the substrate 10. More specifically, as shown in FIG. 2, the first switch unit 1, the second switch unit 2, and the control unit 3 are formed over the multilayer structural portion 13 and a region including only the first main surface 101 among the first main surface 101 and the second main surface 102 of the substrate 10 in the thickness direction D3 of the substrate 10.

As shown in FIG. 1, the first switch unit 1 includes the first common terminal 11 connected to an antenna terminal T1 (see FIG. 9) and the plurality (for example, eight) of first selection terminals 12 that are connectable to the first common terminal 11. The first switch unit 1 includes, for example, a plurality of first switching elements (not shown). The plurality of first switching elements include a plurality (for example, eight) of switching elements (also referred to as first series switching elements below) provided in a plurality (for example, eight) of first signal paths (not shown) between the first common terminal 11 and the plurality (for example, eight) of first selection terminals 12, and a plurality (for example, eight) of switching elements (also referred to as first shunt switching elements below) provided between the plurality of first signal paths and the ground. The first series switching element is, for example, an electric field effect transistor. The first shunt switching element is, for example, an electric field effect transistor. In each of the plurality of first signal paths, the first series switching element is controlled to be in a conduction state, and the first shunt switching element is controlled to be in a non-conduction state, so that the first common terminal 11 and the first selection terminal 12 are connected. In addition, in each of the plurality of first signal paths, both the first series switching element and the first shunt switching element are controlled to be in a non-conduction state, so that the first common terminal 11 and the first selection terminal 12 are not connected. In addition, in each of the plurality of first signal paths, the first series switching element is controlled to be in a non-conduction state, and the first shunt switching element is controlled to be in a conduction state, so that the first common terminal 11 and the first selection terminal 12 are not connected. In each of the electric field effect transistors in the first switch unit 1, a drain region and a source region are formed in the substrate 10, a drain electrode is formed on the drain region, a source electrode is formed on the source region, and a gate electrode is formed on the first main surface 101 of the substrate 10 with a gate insulating film interposed therebetween. Thus, the drain electrode, the source electrode, and the gate electrode of each electric field effect transistor in the first switch unit 1 are included in the multilayer structural portion 13. In addition, each of the plurality of first signal paths of the first switch unit 1 includes at least one wiring portion among the plurality of wiring portions of the multilayer structural portion 13.

The second switch unit 2 includes the second common terminal 21 connected to the transmission circuit 201 (see FIG. 9) and the plurality (for example, eight) of second selection terminals 22 that are connectable to the second common terminal 21. The second switch unit 2 includes, for example, a plurality of second switching elements (not shown). The plurality of second switching elements include a plurality (for example, eight) of switching elements (also referred to as second series switching elements below) provided in a plurality (for example, eight) of second signal paths (not shown) between the second common terminal 21 and the plurality (for example, eight) of second selection terminals 22, and a plurality (for example, eight) of switching elements (also referred to as second shunt switching elements below) provided between the plurality of second signal paths and the ground. The second series switching element is, for example, an electric field effect transistor. The second shunt switching element is, for example, an electric field effect transistor. In each of the plurality of second signal paths, the second series switching element is controlled to be in a conduction state, and the second shunt switching element is controlled to be in a non-conduction state, so that the second common terminal 21 and the second selection terminal 22 are connected. In addition, in each of the plurality of second signal paths, both the second series switching element and the second shunt switching element are controlled to be in a non-conduction state, so that the second common terminal 21 and the second selection terminal 22 are not connected. In addition, in each of the plurality of second signal paths, the second series switching element is controlled to be in a non-conduction state, and the second shunt switching element is controlled to be in a conduction state, so that the second common terminal 21 and the second selection terminal 22 are not connected. In each of the electric field effect transistors in the second switch unit 2, a drain region and a source region are formed in the substrate 10, a drain electrode is formed on the drain region, a source electrode is formed on the source region, and a gate electrode is formed on the first main surface 101 of the substrate 10 with a gate insulating film interposed therebetween. Thus, the drain electrode, the source electrode, and the gate electrode of each electric field effect transistor in the second switch unit 2 are included in the multilayer structural portion 13. In addition, each of the plurality of second signal paths of the second switch unit 2 includes at least one wiring portion among the plurality of wiring portions of the multilayer structural portion 13.

The control unit 3 includes a control circuit that controls at least one of the first switch unit 1 and the second switch unit 2 in accordance with a control signal. The control signal is a digital control signal provided from an external circuit (for example, the signal processing circuit 301 of the communication device 300). The control circuit controls at least one of the first switch unit 1 and the second switch unit 2 based on control signals that are outputted from the signal processing circuit 301 and inputted to the plurality of control terminals 43.

The plurality of external terminals include the first common terminal 11 and the plurality (for example, eight) of first selection terminals 12 included in the first switch unit 1, the second common terminal 21 and the plurality of second selection terminals 22 included in the second switch unit 2, the plurality (for example, seven) of first terminals 4, the plurality (for example, five) of second terminals 5, and the plurality (for example, five) of third terminals 6.

Each of the first common terminal 11 and the plurality of first selection terminals 12 is an RF terminal through which a radio frequency signal (transmission signal, reception signal) passes.

Each of the second common terminal 21 and the plurality of second selection terminals 22 is an RF terminal through which a radio frequency signal (transmission signal) passes.

The plurality (for example, seven) of first terminals 4 include at least one control terminal 43 (here, all four control terminals 43) among the plurality (for example, four) of control terminals 43 to which the above-described control signals are inputted, and a plurality (for example, three) of ground terminals 41. The plurality of control terminals 43 function as an interface for inputting the control signal from the signal processing circuit 301 to the IC chip 100, in the IC chip 100. The plurality of ground terminals 41 include the ground terminal (digital ground terminal) of the control unit 3.

The plurality (for example, five) of second terminals 5 include a plurality (for example, five) of ground terminals 51. The plurality of ground terminals 51 include the ground terminal of the control unit 3. The plurality of ground terminals 51 may include one or more ground terminals (analog ground terminals) to which a plurality of first shunt switching elements are connected.

The plurality (for example, five) of third terminals 6 include a plurality (for example, five) of ground terminals 61. The plurality of ground terminals 61 include the ground terminal of the control unit 3. The plurality of ground terminals 61 may include one or more ground terminals (analog ground terminals) to which a plurality of second shunt switching elements are connected.

In FIG. 1, dot hatching is applied to the plurality of control terminals 43, and cross hatching is applied to the plurality of ground terminals (the plurality of ground terminals 41, the plurality of ground terminals 51, and the plurality of ground terminals 61). However, the dot hatching and the cross hatching do not represent the cross section and are applied only to make the positional relationship between the plurality of control terminals 43 and the plurality of ground terminals easier to understand. As shown in FIG. 1, the plurality of control terminals 43 are surrounded by a plurality of ground terminals in plan view from the thickness direction D3 of the substrate 10. Each of the plurality of external terminals includes, for example, a spherical conductive bump. A material of the conductive bump is, for example, a solder. In plan view from the thickness direction D3 of the substrate 10, an outer edge of each of the plurality of external terminals has a circular shape.

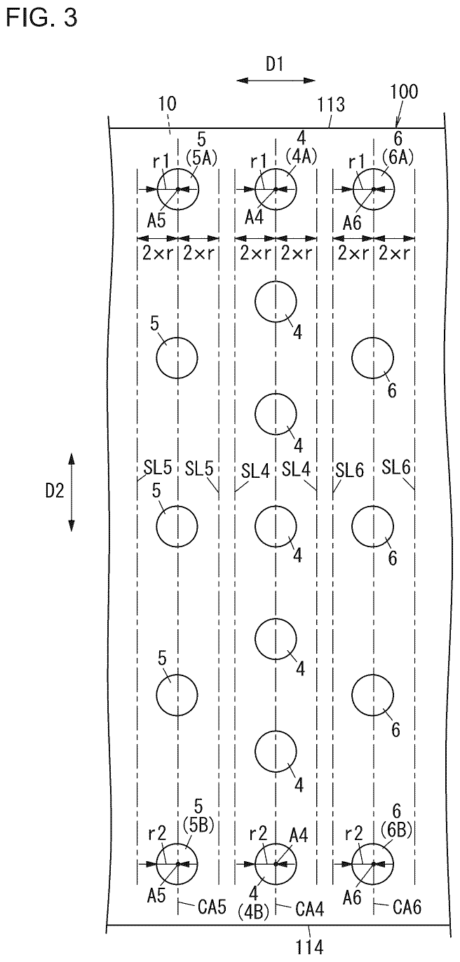

As shown in FIG. 1, the plurality of first terminals 4 are located between the first switch unit 1 and the second switch unit 2 in the first direction D1 in plan view from the thickness direction D3 of the substrate 10. The plurality of first terminals 4 are arranged in a line in the second direction D2 intersecting with the first direction D1. For example, the second direction D2 is a direction perpendicular to the first direction D1. The expression that “the plurality of first terminals 4 are arranged in a line in the second direction D2” means that, as shown in FIG. 3, in plan view from the thickness direction D3 of the substrate 10, at least a part of each first terminal 4 other than a first terminal 4A and a first terminal 4B is located between two straight lines SL4 where a distance from a center line CA4 to one of the straight lines SL4 in the first direction D1 is 2×r. The first terminal 4A is a first terminal 4 on one side (the uppermost side in FIG. 3) in the second direction D2 among the plurality of first terminals 4. The first terminal 4B is a first terminal 4 on the other side (the lowest side in FIG. 3) in the second direction D2 among the plurality of first terminals 4. The center line CA4 is a straight line passing through the center A4 of the first terminal 4A and the center A4 of the first terminal 4B. r is the average value of the radius r1 of the first terminal 4A and the radius r2 of the first terminal 4B when the radius of the first terminal 4A is set as r1 and the radius of the first terminal 4B is set as r2.

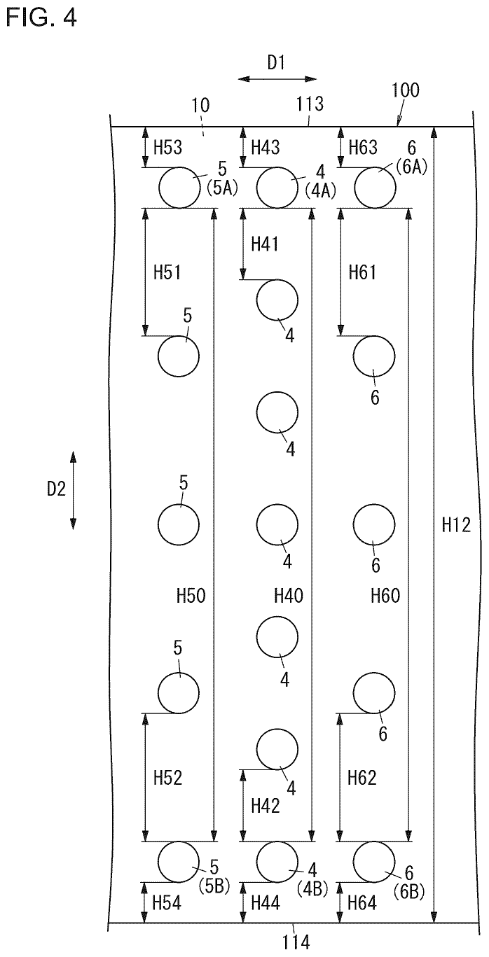

In the IC chip 100, as shown in FIG. 4, in plan view from the thickness direction D3 of the substrate 10, the shortest distance H40 between the first terminal 4A closest to the third side 113 and the first terminal 4B closest to the fourth side 114 among the plurality of first terminals 4 is longer than three-quarters of the shortest distance H12 between the third side 113 and the fourth side 114. In addition, in the IC chip 100, in plan view from the thickness direction D3 of the substrate 10, the shortest distance H43 between the first terminal 4A closest to the third side 113 among the plurality of first terminals 4 and the third side 113 is shorter than the shortest distance H41 between the first terminal 4A closest to the third side 113 and the first terminal 4 adjacent to the first terminal 4A closest to the third side 113. In addition, in the IC chip 100, the shortest distance H44 between the first terminal 4B closest to the fourth side 114 among the plurality of first terminals 4 and the fourth side 114 is shorter than the shortest distance H42 between the first terminal 4B closest to the fourth side 114 and the first terminal 4 adjacent to the first terminal 4B closest to the fourth side 114.

As shown in FIG. 1, the plurality of second terminals 5 are located between the plurality of first terminals 4 and the first switch unit 1 in plan view from the thickness direction D3 of the substrate 10. In the second direction D2, the plurality of second terminals 5 are arranged in a line. The expression that “the plurality of second terminals 5 are arranged in a line in the second direction D2” means that, as shown in FIG. 3, in plan view from the thickness direction D3 of the substrate 10, at least a part of each second terminal 5 other than a second terminal 5A and a second terminal 5B is located between two straight lines SL5 where a distance from a center line CA5 to one of the straight lines SL5 in the first direction D1 is 2×r. The second terminal 5A is a second terminal 5 on one side (the uppermost side in FIG. 3) in the second direction D2 among the plurality of second terminals 5. The second terminal 5B is a second terminal 5 on the other side (the lowest side in FIG. 3) in the second direction D2 among the plurality of second terminals 5. The center line CA5 is a straight line passing through the center A5 of the second terminal 5A and the center A5 of the second terminal 5B. r is the average value of the radius r1 of the second terminal 5A and the radius r2 of the second terminal 5B when the radius of the second terminal 5A is set as r1 and the radius of the second terminal 5B is set as r2.

In the IC chip 100, as shown in FIG. 4, in plan view from the thickness direction D3 of the substrate 10, the shortest distance H50 between the second terminal 5A closest to the third side 113 and the second terminal 5B closest to the fourth side 114 among the plurality of second terminals 5 is longer than three-quarters of the shortest distance H12 between the third side 113 and the fourth side 114. In addition, in the IC chip 100, in plan view from the thickness direction D3 of the substrate 10, the shortest distance H53 between the second terminal 5A closest to the third side 113 among the plurality of second terminals 5 and the third side 113 is shorter than the shortest distance H51 between the second terminal 5A closest to the third side 113 and the second terminal 5 adjacent to the second terminal 5A closest to the third side 113. In addition, in the IC chip 100, the shortest distance H54 between the second terminal 5B closest to the fourth side 114 among the plurality of second terminals 5 and the fourth side 114 is shorter than the shortest distance H52 between the second terminal 5B closest to the fourth side 114 and the second terminal 5 adjacent to the second terminal 5B closest to the fourth side 114.

As shown in FIG. 1, the plurality of third terminals 6 are disposed between the first switch unit 1 and the second switch unit 2 in the first direction D1 in plan view from the thickness direction D3 of the substrate 10. The plurality of third terminals 6 are arranged in a line in the second direction D2. The expression that “the plurality of third terminals 6 are arranged in a line in the second direction D2” means that, as shown in FIG. 3, in plan view from the thickness direction D3 of the substrate 10, at least a part of each third terminal 6 other than a third terminal 6A and a third terminal 6B is located between two straight lines SL6 where a distance from a center line CA6 to one of the straight lines SL6 in the first direction D1 is 2×r. The third terminal 6A is a third terminal 6 on one side (the uppermost side in FIG. 3) in the second direction D2 among the plurality of third terminals 6. The third terminal 6B is a third terminal 6 on the other side (the lowest side in FIG. 3) in the second direction D2 among the plurality of third terminals 6. The center line CA6 is a straight line passing through the center A6 of the third terminal 6A and the center A6 of the third terminal 6B. r is the average value of the radius r1 of the third terminal 6A and the radius r2 of the third terminal 6B when the radius of the third terminal 6A is set as r1 and the radius of the third terminal 6B is set as r2.

In the IC chip 100, as shown in FIG. 4, in plan view from the thickness direction D3 of the substrate 10, the shortest distance H60 between the third terminal 6A closest to the third side 113 and the third terminal 6B closest to the fourth side 114 among the plurality of third terminals 6 is longer than three-quarters of the shortest distance H12 between the third side 113 and the fourth side 114. In addition, in the IC chip 100, in plan view from the thickness direction D3 of the substrate 10, the shortest distance H63 between the third terminal 6A closest to the third side 113 among the plurality of third terminals 6 and the third side 113 is shorter than the shortest distance H61 between the third terminal 6A closest to the third side 113 and the third terminal 6 adjacent to the third terminal 6A closest to the third side 113. In addition, in the IC chip 100, the shortest distance H64 between the third terminal 6B closest to the fourth side 114 among the plurality of third terminals 6 and the fourth side 114 is shorter than the shortest distance H62 between the third terminal 6B closest to the fourth side 114 and the third terminal 6 adjacent to the third terminal 6B closest to the fourth side 114.

In the IC chip 100, as shown in FIG. 1, in plan view from the thickness direction D3 of the substrate 10, the plurality of first terminals 4 are located between the plurality of second terminals 5 and the plurality of third terminals 6 in the first direction D1.

The IC chip 100 is mounted on the mounting board 9, for example, by bonding a plurality of external terminals to the mounting board 9.

### (2.4) Structure of Radio Frequency Module

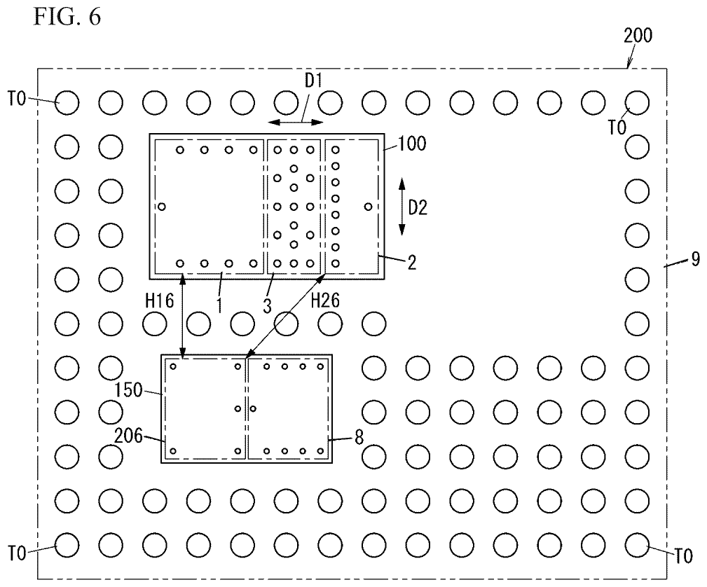

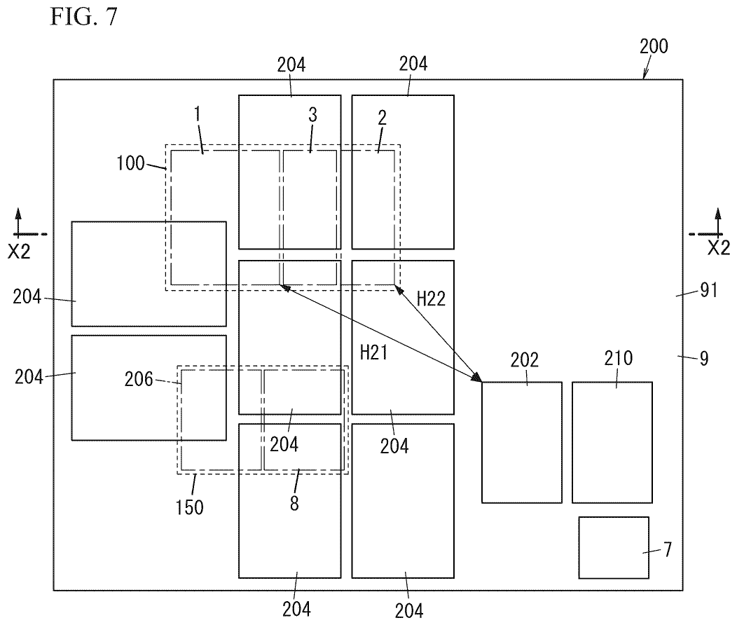

As shown in FIGS. 5 to 8, the radio frequency module 200 includes the IC chip 100 (also referred to as a first IC chip 100 below) and the mounting board 9. The first IC chip 100 includes the first switch unit 1, the second switch unit 2, and the control unit 3. In addition, the radio frequency module 200 includes the third switch unit 7, the plurality (for example, eight) of duplexers 204, the power amplifier 202, the output matching circuit 203 (see FIG. 9), a second IC chip 150, the input matching circuit 207 (see FIG. 9), the controller 210, the low pass filter 209 (see FIG. 9), the plurality (for example, eight) of matching circuits 208 (see FIG. 9), and the plurality of external connection terminals T0. The second IC chip 150 includes the fourth switch unit 8 and the low-noise amplifier 206. In addition, as shown in FIG. 8, the radio frequency module 200 includes a resin layer 120 (also referred to as a first resin layer 120 below), a metal electrode layer 130, and a second resin layer 140. In FIGS. 5 and 7, the first resin layer 120 and the metal electrode layer 130 are not shown. In addition, in FIG. 6, the second resin layer 140 is not shown.

In plan view from a thickness direction D0 (see FIG. 8) of the mounting board 9, an outer edge of the mounting board 9 has a quadrangular shape. As shown in FIG. 8, the mounting board 9 has a first main surface 91 and a second main surface 92 that face each other in the thickness direction D0 of the mounting board 9. Here, the term “facing” means facing geometrically rather than physically. Further, the mounting board 9 has an outer peripheral surface 93. The outer peripheral surface 93 of the mounting board 9 includes, for example, four side surfaces that connect the outer edge of the first main surface 91 and the outer edge of the second main surface 92 of the mounting board 9, and does not include the first main surface 91 or the second main surface 92. That is, the mounting board 9 is a multilayer board including a plurality of dielectric layers and a plurality of conductive layers. The plurality of dielectric layers and the plurality of conductive layers are laminated in the thickness direction D0 of the mounting board 9. The plurality of conductive layers are formed in a predetermined pattern determined for each layer. Each of the plurality of conductive layers includes one or a plurality of conductor portions in a plane perpendicular to the thickness direction D0 of the mounting board 9. A material of each conductive layer is, for example, copper. The plurality of conductive layers include a ground layer. In the radio frequency module 200, the plurality of external ground terminals T5 are electrically connected to the ground layer through a via-conductor and the like of the mounting board 9. The mounting board 9 is, for example, a low temperature co-fired ceramics (LTCC) substrate. The mounting board is not limited to a printed wiring board, and may be, for example, a printed wiring board, a high temperature co-fired ceramics (HTCC) substrate, or a resin multilayer board.

Further, the mounting board 9 is not limited to the LTCC substrate, and may be, for example, a wiring structural body. The wiring structural body is, for example, a multilayer structural body. The multilayer structural body includes at least one insulating layer and at least one conductive layer. The insulating layer is formed in a predetermined pattern. In a case where a plurality of insulating layers are provided, the plurality of insulating layers are formed in a predetermined pattern determined for each layer. The conductive layer is formed in a predetermined pattern different from the predetermined pattern of the insulating layer. In a case where a plurality of conductive layers are provided, the plurality of conductive layers are formed in a predetermined pattern determined for each layer. The conductive layer may include one or a plurality of rewiring portions. In the wiring structural body, a first surface of two surfaces facing each other in the thickness direction of the multilayer structural body is the first main surface 91 of the mounting board 9, and a second surface is the second main surface 92 of the mounting board 9. The wiring structural body may be, for example, an interposer. The interposer may be an interposer using a silicon substrate or may be a substrate constituted by multiple layers.

The first main surface 91 and the second main surface 92 of the mounting board 9 are separated in the thickness direction D0 of the mounting board 9, and intersect with the thickness direction D0 of the mounting board 9. The first main surface 91 of the mounting board 9 is, for example, perpendicular to the thickness direction D0 of the mounting board 9, and may include, for example, a side surface or the like of a conductor portion as a surface that is not perpendicular to the thickness direction D0. In addition, for example, the second main surface 92 of the mounting board 9 is perpendicular to the thickness direction D0 of the mounting board 9, but may include, for example, a side surface or the like of the conductor portion, as a surface that is not perpendicular to the thickness direction D0. Further, the first main surface 91 and the second main surface 92 of the mounting board 9 may be formed with fine unevenness, a recess portion, or a projection portion. For example, when a recess portion is formed on the first main surface 91 of the mounting board 9, the inner surface of the recess portion is included in the first main surface 91.

In the radio frequency module 200, a plurality of first electronic components are mounted at the first main surface 91 of the mounting board 9. The expression that “the first electronic component is mounted at the first main surface 91 of the mounting board 9” includes a case where the first electronic component is disposed (mechanically connected to) at the first main surface 91 of the mounting board 9 and a case where the first electronic component is electrically connected to (an appropriate conductor portion of) the mounting board 9. The plurality of first electronic components include the plurality (for example, eight) of duplexers 204, the power amplifier 202, the third switch unit 7, and the controller 210. The transmission filter 241 and the reception filter 242 (see FIG. 9) in each of the plurality of duplexers 204 are acoustic wave filters. The acoustic wave filter is, for example, a surface acoustic wave filter that uses surface acoustic waves. The power amplifier 202 is a power amplification IC chip. The power amplification IC chip is, for example, a GaAs IC chip in a case where an amplification transistor is a heterojunction bipolar transistor (HBT). In addition, the power amplification IC chip is, for example, a Si-based IC chip, for example, in a case where the amplification transistor is a bipolar transistor or a field effect transistor (FET). In addition, the plurality of first electronic components include a plurality of circuit elements (a plurality of inductors and a plurality of capacitors) of each of the plurality of matching circuits 208. In addition, the plurality of first electronic components include a plurality of circuit elements (a plurality of inductors and a plurality of capacitors) of the output matching circuit 203. In addition, the plurality of first electronic components include a plurality of circuit elements (a plurality of inductors and a plurality of capacitors) of the input matching circuit 207. In FIG. 5, an area E208 in which a plurality of circuit elements of each matching circuit 208 are disposed on the first main surface 91 of the mounting board 9 is shown by a one-dot chain line. Some circuit elements among the plurality of circuit elements of each matching circuit 208 may be built in the mounting board 9. In addition, in FIG. 5, an area E203 in which a plurality of circuit elements of the output matching circuit 203 are disposed on the first main surface 91 of the mounting board 9 is shown by a one-dot chain line. Some circuit elements among the plurality of circuit elements of the output matching circuit 203 may be built in the mounting board 9. In addition, in FIG. 5, an area E207 in which a plurality of circuit elements of the input matching circuit 207 are disposed on the first main surface 91 of the mounting board 9 is shown by a one-dot chain line. Some circuit elements among the plurality of circuit elements of the input matching circuit 207 may be built in the mounting board 9. An outer edge of each of the plurality of first electronic components has, for example, a quadrangular shape in plan view from the thickness direction D0 of the mounting board 9. The circuit elements of the low pass filter 209 are built in the mounting board 9, but the present disclosure is not limited thereto. The plurality of first electronic components may include the circuit elements of the low pass filter 209.

In the radio frequency module 200, a plurality of second electronic components are mounted at the second main surface 92 of the mounting board 9. The plurality of second electronic components include the first IC chip 100 and the second IC chip 150. The phrase that “the second electronic component is mounted at the second main surface 92 of the mounting board 9” includes a case where the second electronic component is disposed (mechanically connected to) on the second main surface 92 of the mounting board 9 and a case where the second electronic component is electrically connected to (an appropriate conductor portion of) the mounting board 9. An outer edge of each of the plurality of second electronic components has, for example, a quadrangular shape in plan view from the thickness direction D0 of the mounting board 9. Since the second IC chip 150 including the low-noise amplifier 206 is mounted at the second main surface 92 of the mounting board 9, the low-noise amplifier 206 is disposed on the second main surface 92 of the mounting board 9.

The plurality of external connection terminals T0 (see FIGS. 6 and 8) are disposed on the second main surface 92 of the mounting board 9. The phrase that “the external connection terminal T0 is disposed on the second main surface 92 of the mounting board 9” includes that the external connection terminal T0 is mechanically connected to the second main surface 92 of the mounting board 9 and the external connection terminal T0 is electrically connected to the (appropriate conductor portion of) mounting board 9.

As shown in FIG. 9, the plurality of external connection terminals T0 include the antenna terminal T1, the two signal input terminals T2, the four external control terminals T3, the signal output terminal T4, and the plurality of external ground terminals T5 (see FIG. 8). The plurality of external ground terminals T5 are electrically connected to a ground layer of the mounting board 9. The ground layer is a circuit ground of the radio frequency module 200, and the plurality of first electronic components of the radio frequency module 200 include electronic components that are electrically connected to the ground layer. In addition, the plurality of second electronic components of the radio frequency module 200 include electronic components that are electrically connected to the ground layer. In the radio frequency module 200, each of the plurality of ground terminals (the plurality of ground terminals 41, the plurality of ground terminals 51, and the plurality of ground terminals 61 shown in FIG. 1) of the IC chip 100 is connected to at least one external ground terminal T5 among the external ground terminals T5 of the radio frequency module 200.

Materials of the plurality of external connection terminals T0 are, for example, metal (for example, copper, copper alloy, or the like). The plurality of external connection terminals T0 are not constituent elements of the mounting board 9, but may be constituent elements of the mounting board 9. Each of the plurality of external connection terminals T0 is a columnar-shaped electrode (for example, a cylindrical-shaped electrode).

As shown in FIG. 8, the first resin layer 120 is disposed on the first main surface 91 of the mounting board 9. The first resin layer 120 contains a resin (for example, an epoxy resin). The first resin layer 120 may contain a filler in addition to a resin. The first resin layer 120 has electrical insulating properties.

The first resin layer 120 covers at least a part of each of the plurality of first electronic components disposed on the first main surface 91 of the mounting board 9. The first resin layer 120 covers an outer peripheral surface 2043 of each of the duplexers 204 but does not cover a main surface 2041 on a side opposite from the mounting board 9. The outer peripheral surface 2043 of each of the duplexers 204 does not include the main surface 2041 on the side opposite from the mounting board 9 or a main surface on the mounting board 9 side.

The metal electrode layer 130 covers the main surface 2041 of the plurality of duplexers 204 on the side opposite from the mounting board 9, a main surface 121 of the first resin layer 120 on a side opposite from the mounting board 9, an outer peripheral surface 123 of the first resin layer 120, the outer peripheral surface 93 of the mounting board 9, and an outer peripheral surface 143 of the second resin layer 140. The metal electrode layer 130 is in contact with at least a part of an outer peripheral surface of the ground layer of the mounting board 9. As a result, it is possible to set a potential of the metal electrode layer 130 to be the same as a potential of the ground layer. The metal electrode layer 130 has a multilayer structure in which a plurality of metal layers are laminated, but the present disclosure is not limited thereto, and the metal electrode layer 130 may be formed of one metal layer. The metal layer contains one type or a plurality of types of metals. In a case where the metal electrode layer 130 has a multilayer structure in which a plurality of metal layers are laminated, the metal electrode layer 130 includes, for example, a first metal layer (for example, a first stainless steel layer), a second metal layer (for example, a Cu layer) on the first metal layer, and a third metal layer (for example, a second stainless steel layer) on the second metal layer. A material of each of the first stainless steel layer and the second stainless steel layer is an alloy including Fe, Ni, and Cr. In addition, the metal electrode layer 130 is, for example, a Cu layer when it is formed of one metal layer.

In the radio frequency module 200, the metal electrode layer 130 is in contact with the entire area of the main surface 2041 of each of the plurality of duplexers 204.

The second resin layer 140 covers the first IC chip 100, the second IC chip 150, and an outer peripheral surface of each of the plurality of external connection terminals T0. The second resin layer 140 contains resin (for example, epoxy resin). The second resin layer 140 may contain a filler in addition to the resin. A material of the second resin layer 140 may be the same material as the material of the first resin layer 120 or may be a different material. The second resin layer 140 covers the main surface 1002 of the first IC chip 100 on a side opposite from the mounting board 9 and the outer peripheral surface 1003 of the first IC chip 100, but the present disclosure is not limited thereto. The second resin layer 140 does not need to cover the main surface 1002 of the first IC chip 100 on the side opposite from the mounting board 9. The second resin layer 140 covers the main surface of the second IC chip 150 on a side opposite from the mounting board 9 and the outer peripheral surface of the second IC chip 150, but the present disclosure is not limited thereto. The second resin layer 140 does not need to cover the main surface of the second IC chip 150 on the side opposite from the mounting board 9. In addition, the second resin layer 140 does not cover end surfaces T01 of the plurality of external connection terminals T0 on a side opposite from the mounting board 9. For example, a main surface 141 of the second resin layer 140 on a side opposite from the mounting board 9 is flush with the end surface T01 of each external connection terminal T0.

In the radio frequency module 200, as shown in FIG. 6, in plan view from the thickness direction D0 of the mounting board 9, the shortest distance H26 between the low-noise amplifier 206 and the second switch unit 2 is longer than the shortest distance H16 between the low-noise amplifier 206 and the first switch unit 1.

In the radio frequency module 200, as shown in FIG. 7, in plan view from the thickness direction D0 of the mounting board 9, the shortest distance H22 between the power amplifier 202 and the second switch unit 2 is shorter than the shortest distance H21 between the power amplifier 202 and the first switch unit 1.

### (2.5) Structure of Communication Device

As described above, the communication device 300 includes the radio frequency module 200 and the signal processing circuit 301. The plurality of electronic components that configure the signal processing circuit 301 may be mounted on, for example, the above-described circuit board, or may be mounted on a circuit board (second circuit board) different from the circuit board (first circuit board) on which the radio frequency module 200 is mounted.

### (3) Effects

### (3.1) IC Chip

As shown in FIGS. 1 and 2, the IC chip 100 according to Embodiment 1 includes the substrate 10, the first switch unit 1, the second switch unit 2, the control unit 3, the plurality of first terminals 4, and the plurality of second terminals 5. The first switch unit 1 is formed at the substrate 10. The first switch unit 1 includes the first common terminal 11 connected to the antenna terminal T1 and the plurality of first selection terminals 12 that are connectable to the first common terminal 11. The second switch unit 2 is formed at the substrate 10. The second switch unit 2 includes the second common terminal 21 connected to the transmission path Ru1 and the plurality of second selection terminals 22 that are connectable to the second common terminal 21. The control unit 3 is formed at the substrate 10. The control unit 3 is connected to at least one of the first switch unit 1 and the second switch unit 2. In plan view from a thickness direction D3 of the substrate 10, the plurality of first terminals 4 are located between the first switch unit 1 and the second switch unit 2 in the first direction D1 and are arranged in a line in the second direction D2 intersecting with the first direction D1. For example, the second direction D2 is a direction perpendicular to the first direction D1. In plan view from the thickness direction D3 of the substrate 10, the plurality of second terminals 5 are located between the plurality of first terminals 4 and the first switch unit 1 and are arranged in a line in the second direction D2. The plurality of first terminals 4 are connected to the control unit 3. The plurality of first terminals 4 include at least one control terminal 43 among the plurality of control terminals 43. The plurality of second terminals 5 include the ground terminal 51.

With the IC chip 100 according to Embodiment 1, it is possible to improve the isolation between the first switch unit 1 and the second switch unit 2 different from each other. More specifically, with the IC chip 100 according to Embodiment 1, the plurality of first terminals 4 connected to the control unit 3 are arranged in a line in the second direction D2, the plurality of second terminals 5 located between the plurality of first terminals 4 and the first switch unit 1 are arranged in a line in the second direction D2, the plurality of first terminals 4 include at least one control terminal 43, and the plurality of second terminals 5 include the ground terminal 51. As shown in FIG. 9, since the second switch unit 2 is connected to the transmission path Ru1 and is connected to the power amplifier 202, the transmission signal from the power amplifier 202 is inputted. Since the transmission signal inputted to the second switch unit 2 is a signal before passing through the transmission filter 241, in the second switch unit 2, a transmission signal having power higher than a transmission signal after passing through the transmission filter 241 passes through the circuit in the second switch unit 2. In this case, in a case where the first switch unit 1 and the second switch unit 2 are formed to be integrated in the IC chip 100 as in Embodiment 1, the transmission signal from the second switch unit 2 is likely to leak to the first switch unit 1. However, by disposing the control unit 3 between the first switch unit 1 and the second switch unit 2 and providing a plurality of terminal lines between the first switch unit 1 and the second switch unit 2 in the control unit 3, it is possible to improve the isolation between the first switch unit 1 and the second switch unit 2.

In addition, in the IC chip 100 according to Embodiment 1, the plurality of first terminals 4 include all of the plurality of control terminals 43 and further include a second ground terminal (ground terminal 41) separate from the first ground terminal 51 that is the ground terminal 51. As a result, in the IC chip 100 according to Embodiment 1, it is possible to further improve the isolation between the first switch unit 1 and the second switch unit 2 different from each other.

In addition, the IC chip 100 according to Embodiment 1 further includes the plurality of third terminals 6. The plurality of third terminals 6 are disposed between the first switch unit 1 and the second switch unit 2 in the first direction D1 in plan view from the thickness direction D3 of the substrate 10. The plurality of third terminals 6 are arranged in a line in the second direction D2. The plurality of third terminals 6 include the ground terminal 61. As a result, the IC chip 100 according to Embodiment 1 can further improve the isolation between the first switch unit 1 and the second switch unit 2 different from each other.

In addition, in the IC chip 100 according to Embodiment 1, the outer edge 110 of the IC chip 100 includes the first side 111 and the second side 112 that face each other in the first direction D1, and the third side 113 and the fourth side 114 that face each other in the second direction D2. In plan view from the thickness direction D3 of the substrate 10, the shortest distance H40 between the first terminal 4 closest to the third side 113 and the first terminal 4 closest to the fourth side 114 among the plurality of first terminals 4 is longer than three-quarters of the shortest distance H12 between the third side 113 and the fourth side 114. As a result, the IC chip 100 according to Embodiment 1 can further improve the isolation between the first switch unit 1 and the second switch unit 2.

In addition, in the IC chip 100 according to Embodiment 1, in plan view from the thickness direction D3 of the substrate 10, the shortest distance H43 between the first terminal 4 (4A) closest to the third side 113 among the plurality of first terminals 4 and the third side 113 is shorter than the shortest distance H41 between the first terminal 4 (4A) closest to the third side 113 and the first terminal 4 adjacent to the first terminal 4 (4A) closest to the third side 113. The shortest distance H44 between the first terminal 4 (4B) closest to the fourth side 114 among the plurality of first terminals 4 and the fourth side 114 is shorter than the shortest distance H42 between the first terminal 4 (4B) closest to the fourth side 114 and the first terminal 4 adjacent to the first terminal 4 (4B) closest to the fourth side 114. As a result, the IC chip 100 according to Embodiment 1 can further improve the isolation between the first switch unit 1 and the second switch unit 2.

### (3.2) Radio Frequency Module

The radio frequency module 200 according to Embodiment 1 includes the mounting board 9 and the IC chip 100. As a result, the radio frequency module 200 according to Embodiment 1 can improve the isolation between the first switch unit 1 and the second switch unit 2 different from each other.

In addition, in the radio frequency module 200 according to Embodiment 1, the plurality of duplexers 204, each of which is connected to the plurality of first selection terminals 12 of the first switch unit 1 and includes the transmission filter 241 and the reception filter 242, are further included, and the transmission filters 241 of the plurality of duplexers 204 are connected to the plurality of second selection terminals 22 of the second switch unit 2. As a result, the radio frequency module 200 according to Embodiment 1 can suppress the leakage of a transmission signal passing through the transmission filter 241 to the reception filter 242 by bypassing the first switch unit 1, and can suppress the deterioration in both transmission characteristics and reception characteristics.

In addition, the radio frequency module 200 according to Embodiment 1 further includes the plurality of external connection terminals T0 and the power amplifier 202 connected to the transmission path Ru1. The mounting board 9 has the first main surface 91 and the second main surface 92 that face each other. The power amplifier 202 is disposed on the first main surface 91 of the mounting board 9. The plurality of external connection terminals T0 and the IC chip 100 are disposed on the second main surface 92 of the mounting board 9. In plan view from the thickness direction D0 of the mounting board 9, the shortest distance H22 between the power amplifier 202 and the second switch unit 2 is shorter than the shortest distance H21 between the power amplifier 202 and the first switch unit 1. As a result, the radio frequency module 200 according to Embodiment 1 can further shorten the signal path (a part of the transmission path Ru1) between the power amplifier 202 and the second switch unit 2.

In addition, the radio frequency module 200 according to Embodiment 1 further includes the low-noise amplifier 206. The low-noise amplifier 206 is disposed on the second main surface 92 of the mounting board 9. The low-noise amplifier 206 is connectable to at least one first selection terminals 12 among the plurality of first selection terminals 12. In plan view from the thickness direction D0 of the mounting board 9, the shortest distance H26 between the low-noise amplifier 206 and the second switch unit 2 is longer than the shortest distance H16 between the low-noise amplifier 206 and the first switch unit 1. As a result, the radio frequency module 200 according to Embodiment 1 can improve the isolation between the low-noise amplifier 206 and the second switch unit 2.

### (3.3) Communication Device

The communication device 300 according to Embodiment 1 includes the radio frequency module 200 and the signal processing circuit 301. As a result, the communication device 300 according to Embodiment 1 can improve the isolation between the first switch unit 1 and the second switch unit 2 different from each other.

### (4) Modification Examples of Embodiment 1

### (4.1) Modification Example 1

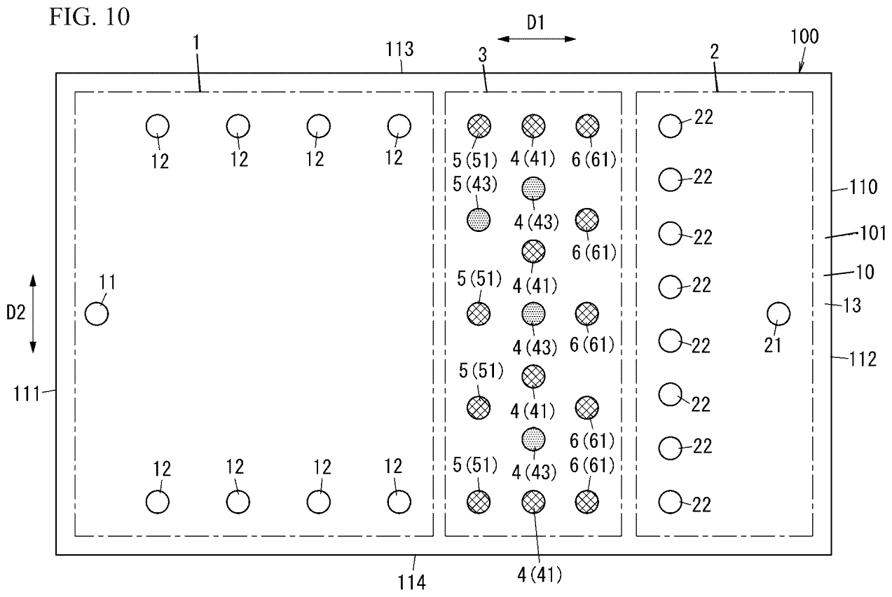

In an IC chip 100 according to Modification Example 1, as shown in FIG. 10, the plurality of first terminals 4 further include a second ground terminal (ground terminal 41) that is separate from the first ground terminal 51 that is the ground terminal 51, and the plurality of second terminals 5 further include a control terminal 43 that is not included in the plurality of first terminals 4 among the plurality of control terminals 43. In FIG. 10, dot hatching is applied to the plurality of control terminals 43, and cross hatching is applied to the plurality of ground terminals (the plurality of ground terminals 41, the plurality of ground terminals 51, and the plurality of ground terminals 61). However, the dot hatching and the cross hatching do not represent the cross section and are applied only to make the relationship between the plurality of control terminals 43 and the plurality of ground terminals easier to understand. Other configurations of the IC chip 100 according to Modification Example 1 are the same as those of the IC chip 100 (see FIG. 1) according to Embodiment 1, and it is possible to improve the isolation between the first switch unit 1 and the second switch unit 2.

### (4.2) Modification Example 2

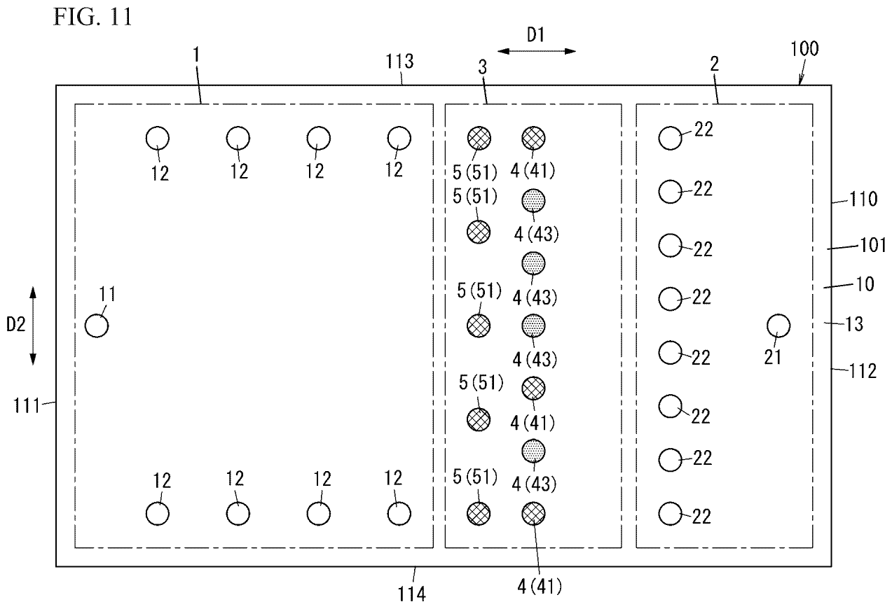

As shown in FIG. 11, an IC chip 100 according to Modification Example 2 differs from the IC chip 100 according to Embodiment 1 in that the IC chip 100 according to Modification Example 2 does not include the plurality of third terminals 6 in the IC chip 100 according to Embodiment 1 (see FIG. 1). In FIG. 11, dot hatching is applied to the plurality of control terminals 43, and cross hatching is applied to the plurality of ground terminals (the plurality of ground terminals 41 and the plurality of ground terminals 51). However, the dot hatching and the cross hatching do not represent the cross section and are applied only to make the positional relationship between the plurality of control terminals 43 and the plurality of ground terminals easier to understand. Other configurations of the IC chip 100 according to Modification Example 2 are the same as those of the IC chip 100 according to Embodiment 1. The IC chip 100 according to Modification Example 2 can improve the isolation between the first switch unit 1 and the second switch unit 2, as in the IC chip 100 according to Embodiment 1.

### (4.3) Modification Example 3

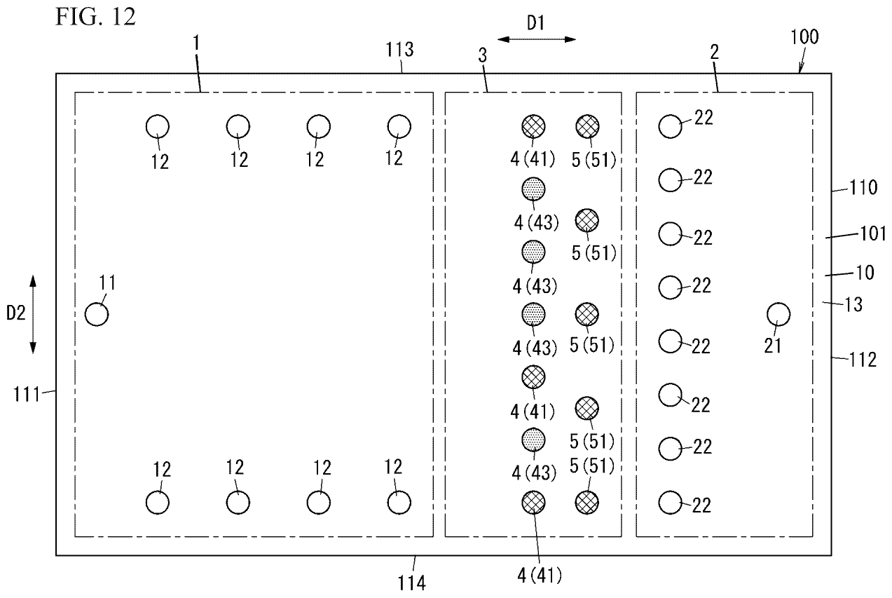

As shown in FIG. 12, an IC chip 100 according to Modification Example 3 differs from the IC chip 100 according to Embodiment 1 in that the IC chip 100 according to Modification Example 3 does not include the plurality of third terminals 6, and the plurality of second terminals 5 are located between the plurality of first terminals 4 and the second switch unit 2 in the IC chip 100 according to Embodiment 1 (see FIG. 1). In FIG. 12, dot hatching is applied to the plurality of control terminals 43, and cross hatching is applied to the plurality of ground terminals (the plurality of ground terminals 41 and the plurality of ground terminals 51). However, the dot hatching and the cross hatching do not represent the cross section and are applied only to make the positional relationship between the plurality of control terminals 43 and the plurality of ground terminals easier to understand. Other configurations of the IC chip 100 according to Modification Example 3 are the same as those of the IC chip 100 according to Embodiment 1. The IC chip 100 according to Modification Example 3 can improve the isolation between the first switch unit 1 and the second switch unit 2, as in the IC chip 100 according to Embodiment 1.

### Embodiment 2

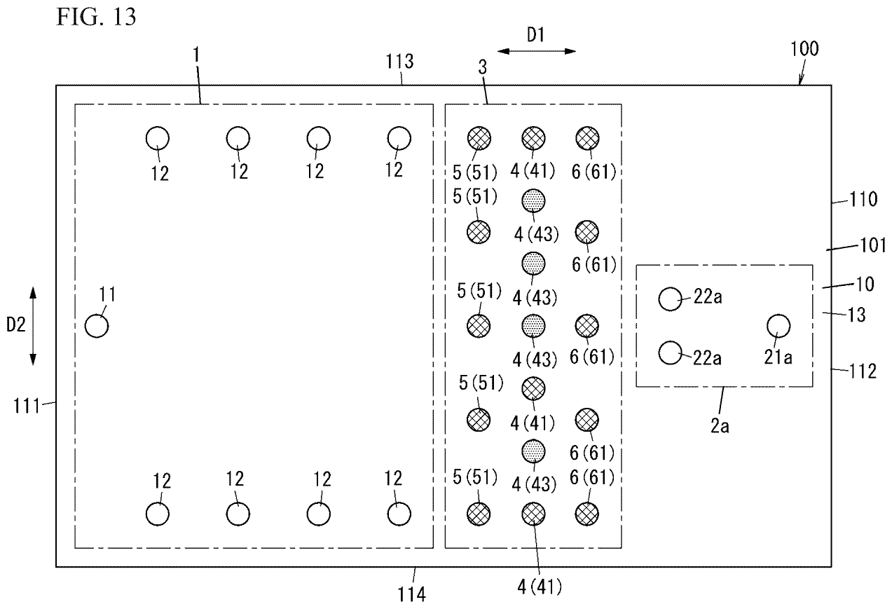

As shown in FIG. 13, an IC chip 100 according to Embodiment 2 differs from the IC chip 100 according to Embodiment 1 in that the IC chip 100 according to Embodiment 2 includes a second switch unit 2a corresponding to the third switch unit 7 in the radio frequency module 200 (see FIG. 9) according to Embodiment 1 instead of the second switch unit 2 in the IC chip 100 (see FIG. 1) according to Embodiment 1. The second switch unit 2a includes a second common terminal 21a (corresponding to the third common terminal 71 in FIG. 9) and a plurality (for example, two) of second selection terminals 22a (corresponding to the plurality of third selection terminals 72 in FIG. 9) that are connectable to the second common terminal 21a. In FIG. 13, dot hatching is applied to the plurality of control terminals 43, and cross hatching is applied to the plurality of ground terminals (the plurality of ground terminals 41, the plurality of ground terminals 51, and the plurality of ground terminals 61). However, the dot hatching and the cross hatching do not represent the cross section and are applied only to make the positional relationship between the plurality of control terminals 43 and the plurality of ground terminals easier to understand. In the IC chip 100 according to Embodiment 2, the second common terminal 21a of the second switch unit 2a is a terminal that is connected to the transmission path Ru1 and is connected to the input terminal 221 of the power amplifier 202 included in the transmission circuit 201 (see FIG. 9). In addition, the plurality of second selection terminals 22a of the second switch unit 2a include a plurality (two) of terminals to which transmission signals different from each other are inputted. The plurality of terminals to which the transmission signals different from each other are inputted in the plurality of second selection terminals 22a are connected to the plurality of signal input terminals T2 in the radio frequency module 200 (see FIG. 9).

In the IC chip 100 according to Embodiment 2, the plurality of first terminals 4 connected to the control unit 3 are arranged in a line in the second direction D2, the plurality of second terminals 5 located between the plurality of first terminals 4 and the first switch unit 1 are arranged in a line in the second direction D2, the plurality of first terminals 4 include at least one control terminal 43, and the plurality of second terminals 5 include the ground terminal 51. Thus, it is possible to improve the isolation between the first switch unit 1 and the second switch unit 2a.

### Modification Examples

Embodiments 1 and 2 and the like described above are merely one of various embodiments of the present disclosure. Various modifications of Embodiments 1 and 2 and the like described above can be made according to the design or the like as long as the possible benefit of the present disclosure can be achieved.

For example, in the IC chip 100 according to Embodiment 1, the control unit 3 is not limited to the configuration in which the control unit 3 controls both the first switch unit 1 and the second switch unit 2 in accordance with the control signal, and may have a configuration in which the control unit 3 controls at least one of the first switch unit 1 and the second switch unit 2 in accordance with the control signal.

In addition, the IC chip 100 according to Embodiment 1 may further include the third switch unit 7. In this case, the third switch unit 7 only needs to be located on an opposite side of the first switch unit 1 side in the first direction D1 as viewed from the plurality of first terminals 4 and the plurality of second terminals 5.

For example, in the radio frequency module 200, the IC chip 100 is disposed at the mounting board 9 such that the first main surface 101 among the first main surface 101 and the second main surface 102 of the substrate 10 is located on the mounting board 9 side. However, the present disclosure is not limited thereto. The IC chip 100 may be disposed at the mounting board 9 such that the second main surface 102 among the first main surface 101 and the second main surface 102 of the substrate 10 is located on the mounting board 9 side.

In addition, each of the plurality of transmission filters 241 and the plurality of reception filters 242 is not limited to being a surface acoustic wave filter and may also be a bulk acoustic wave filter. In addition, each of the plurality of transmission filters 241 and the plurality of reception filters 242 may be, for example, an acoustic wave filter using a boundary acoustic wave, a plate wave, or the like.

In addition, in the radio frequency module 200, the controller 210 is disposed on the first main surface 91 of the mounting board 9, but the present disclosure is not limited thereto. The controller 210 may be disposed on the second main surface 92 of the mounting board 9.

In addition, in the radio frequency module 200, the low-noise amplifier 206 is disposed on the second main surface 92 of the mounting board 9, but the present disclosure is not limited thereto. The low-noise amplifier 206 may be disposed on the first main surface 91 of the mounting board 9.

Each of the plurality of external connection terminals T0 is not limited to the case of being a columnar-shaped electrode, and may be, for example, a ball-shaped bump. A material of the ball-shaped bump that configures each of the plurality of external connection terminals T0 is, for example, gold, copper, solder, and the like.

Further, the radio frequency module 200 has a configuration in which a plurality of second electronic components are not mounted on the second main surface 92 of the mounting board 9, but are mounted on the first main surface 91 of the mounting board 9, and may have a configuration in which the second resin layer 140 is not provided.

The circuit configuration of the radio frequency module 200 is not limited to the example in FIG. 9 described above. In addition, the radio frequency module 200 may include a radio frequency front-end circuit that is compatible with multi input multi output (MIMO) or evolved-universal terrestrial radio access new radio dual connectivity (ENDC).

### Aspects

The following aspects are disclosed in the present specification.

An IC chip (100) according to a first aspect includes a substrate (10), a first switch unit (1), a second switch unit (2; 2a), a control unit (3), a plurality of first terminals (4), and a plurality of second terminals (5). The first switch unit (1) is formed at the substrate (10). The first switch unit (1) includes a first common terminal (11) connected to the antenna terminal (T1) and a plurality of first selection terminals (12) that are connectable to the first common terminal (11). The second switch unit (2; 2a) is formed at the substrate (10). The second switch unit (2; 2a) includes a second common terminal (21; 21a) connected to a transmission path (Ru1) and a plurality of second selection terminals (22; 22a) that are connectable to the second common terminal (21; 21a). The control unit (3) is formed at the substrate (10). The control unit (3) is connected to at least one of the first switch unit (1) and the second switch unit (2; 2a). In plan view from a thickness direction (D3) of the substrate (10), a plurality of first terminals (4) are located between the first switch unit (1) and the second switch unit (2; 2a) in a first direction (D1), and are arranged in a line in a second direction (D2) intersecting with the first direction (D1). In plan view from the thickness direction (D3) of the substrate (10), a plurality of second terminals (5) are located between the plurality of first terminals (4), and the first switch unit (1) or the second switch unit (2; 2a), and are arranged in a line in the second direction (D2). The plurality of first terminals (4) include at least one control terminal (43) among a plurality of control terminals (43) connected to the control unit (3). The plurality of second terminals (5) include a ground terminal (51).

With the IC chip (100) according to the first aspect, it is possible to improve the isolation between the first switch unit (1) and the second switch unit (2; 2a) different from each other.

In an IC chip (100) according to a second aspect, in the first aspect, the plurality of first terminals (4) include all of the plurality of control terminals (43).

In an IC chip (100) according to a third aspect, in the second aspect, the plurality of first terminals (4) further include a second ground terminal (ground terminal 41) that is separate from a first ground terminal (51) that is the ground terminal (51).

With the IC chip (100) according to the third aspect, it is possible to improve the isolation between the first switch unit (1) and the second switch unit (2; 2a) different from each other.

In an IC chip (100) according to a fourth aspect, in the first aspect, the plurality of first terminals (4) further include a second ground terminal (ground terminal 41) that is separate from a first ground terminal (51) that is the ground terminal (51). The plurality of second terminals (5) further include a control terminal (43) that is not included in the plurality of first terminals (4) among the plurality of control terminals (43).

An IC chip (100) according to a fifth aspect further in any one of the first to fourth aspects includes a plurality of third terminals (6). In plan view from the thickness direction (D3) of the substrate (10), the plurality of third terminals (6) are disposed between the first switch unit (1) and the second switch unit (2; 2a) in the first direction (D1). The plurality of third terminals (6) are arranged in a line in the second direction (D2). The plurality of third terminals (6) include a ground terminal (61).

With the IC chip (100) according to the fifth aspect, it is possible to further improve the isolation between the first switch unit (1) and the second switch unit (2; 2a) different from each other.

In an IC chip (100) according to a sixth aspect, in the fifth aspect, the plurality of first terminals (4) are located between the plurality of second terminals (5) and the plurality of third terminals (6) in the first direction (D1).

In an IC chip (100) according to a seventh aspect, in any one of the first to sixth aspects, an outer edge (110) of the IC chip (100) includes a first side (111) and a second side (112) that face each other in the first direction (D1), and a third side (113) and a fourth side (114) that face each other in the second direction (D2). In plan view from the thickness direction (D3) of the substrate (10), a shortest distance (H40) between a first terminal (4A) closest to the third side (113) and a first terminal (4B) closest to the fourth side (114) among the plurality of first terminals (4) is longer than three-quarters of a shortest distance (H12) between the third side (113) and the fourth side (114).

With the IC chip (100) according to the seventh aspect, it is possible to further improve the isolation between the first switch unit (1) and the second switch unit (2; 2a).

In an IC chip (100) according to an eighth aspect, in any one of the first to sixth aspects, an outer edge (110) of the IC chip (100) includes a first side (111) and a second side (112) that face each other in the first direction (D1), and a third side (113) and a fourth side (114) that face each other in the second direction (D2). In plan view from the thickness direction (D3) of the substrate (10), a shortest distance (H43) between a first terminal (4A) closest to the third side (113) among the plurality of first terminals (4) and the third side (113) is shorter than a shortest distance (H41) between the first terminal (4A) closest to the third side (113) and a first terminal (4) adjacent to the first terminal (4A) closest to the third side (113). A shortest distance (H44) between a first terminal (4B) closest to the fourth side (114) among the plurality of first terminals (4) and the fourth side (114) is shorter than a shortest distance (H42) between the first terminal (4B) closest to the fourth side (114) and a first terminal (4) adjacent to the first terminal (4B) closest to the fourth side (114).

With the IC chip (100) according to the eighth aspect, it is possible to further improve the isolation between the first switch unit (1) and the second switch unit (2; 2a).

In an IC chip (100) according to a ninth aspect, in any one of the first to eighth aspects, the second common terminal (21) of the second switch unit (2) is a terminal that is connected to the transmission path (Ru1) and is connected to an output terminal (222) of a power amplifier (202). The plurality of second selection terminals (22) of the second switch unit (2) include terminals to which a plurality of transmission filters (241) having pass bands different from each other are connected.

In an IC chip (100) according to a tenth aspect, in any one of the first to eighth aspects, the second common terminal (21a) of the second switch unit (2a) is a terminal that is connected to the transmission path (Ru1) and is connected to an input terminal (221) of a power amplifier (202). The plurality of second selection terminals (22a) of the second switch unit (2a) include a plurality of terminals to which transmission signals different from each other are inputted.

A radio frequency module (200) according to an eleventh aspect includes the IC chip (100) according to any one of the first to tenth aspects, and a mounting board (9) on which the IC chip (100) is disposed.

With the radio frequency module (200) according to the eleventh aspect, it is possible to improve the isolation between the first switch unit (1) and the second switch unit (2; 2a) different from each other.

A radio frequency module (200) according to a twelfth aspect in the eleventh aspect further includes a plurality of external connection terminals (T0), and a power amplifier (202) connected to the transmission path (Ru1). The mounting board (9) has a first main surface (91) and a second main surface (92) that face each other. The power amplifier (202) is disposed on the first main surface (91) of the mounting board (9). The plurality of external connection terminals (T0) and the IC chip (100) are disposed on the second main surface (92) of the mounting board (9). In plan view from the thickness direction (D0) of the mounting board (9), a shortest distance (H22) between the power amplifier (202) and the second switch unit (2; 2a) is shorter than a shortest distance (H21) between the power amplifier (202) and the first switch unit (1).

With the radio frequency module (200) according to the twelfth aspect, it is possible to further shorten the transmission path (Ru1) between the power amplifier (202) and the second switch unit (2; 2a).

A radio frequency module (200) according to a thirteenth aspect in the twelfth aspect further includes a low-noise amplifier (206). The low-noise amplifier (206) is disposed on the second main surface (92) of the mounting board (9). The low-noise amplifier (206) is connectable to at least one first selection terminal (12) among the plurality of first selection terminals (12). In plan view from the thickness direction (D0) of the mounting board (9), a shortest distance (H16) between the low-noise amplifier (206) and the first switch unit (1) is shorter than a shortest distance (H26) between the low-noise amplifier (206) and the second switch unit (2; 2a).

With the radio frequency module (200) according to the thirteenth aspect, it is possible to improve the isolation between the low-noise amplifier (206) and the second switch unit (2; 2a).

A radio frequency module (200) according to a fourteenth aspect in any one of the eleventh to thirteenth aspects further includes a plurality of transmission filters (241) that are connected to a plurality of second selection terminals (22) of the second switch unit (2).

A communication device (300) according to a fifteenth aspect includes the radio frequency module (200) according to any one of the eleventh to fourteenth aspects, and a signal processing circuit (301). The signal processing circuit (301) is connected to the radio frequency module (200).

The communication device (300) according to the fifteenth aspect can improve the isolation between the first switch unit (1) and the second switch unit (2; 2a) different from each other.
1 FIRST SWITCH UNIT
11 FIRST COMMON TERMINAL
12 FIRST SELECTION TERMINAL
2, 2a SECOND SWITCH UNIT
21, 21a SECOND COMMON TERMINAL
22, 22a SECOND SELECTION TERMINAL
4, 4A, 4B FIRST TERMINAL
41 GROUND TERMINAL (SECOND GROUND TERMINAL)
43 CONTROL TERMINAL
5, 5A, 5B SECOND TERMINAL
51 GROUND TERMINAL (FIRST GROUND TERMINAL)
6, 6A, 6B THIRD TERMINAL
61 GROUND TERMINAL
7 THIRD SWITCH UNIT
71 THIRD COMMON TERMINAL
72 THIRD SELECTION TERMINAL
8 FOURTH SWITCH UNIT
81 FOURTH COMMON TERMINAL
82 FOURTH SELECTION TERMINAL
9 MOUNTING BOARD
91 FIRST MAIN SURFACE
92 SECOND MAIN SURFACE
93 OUTER PERIPHERAL SURFACE
10 SUBSTRATE
101 MAIN SURFACE (FIRST MAIN SURFACE)
102 SECOND MAIN SURFACE
103 OUTER PERIPHERAL SURFACE
100 IC CHIP (FIRST IC CHIP)
110 OUTER EDGE
111 FIRST SIDE
112 SECOND SIDE
113 THIRD SIDE
114 FOURTH SIDE
1002 MAIN SURFACE
1003 OUTER PERIPHERAL SURFACE
120 RESIN LAYER (FIRST RESIN LAYER)
121 MAIN SURFACE
123 OUTER PERIPHERAL SURFACE
130 METAL ELECTRODE LAYER
140 SECOND RESIN LAYER
141 MAIN SURFACE
143 OUTER PERIPHERAL SURFACE
200 RADIO FREQUENCY MODULE
201 TRANSMISSION CIRCUIT
202 POWER AMPLIFIER
221 INPUT TERMINAL
222 OUTPUT TERMINAL
203 OUTPUT MATCHING CIRCUIT
204 DUPLEXER
241 TRANSMISSION FILTER
242 RECEPTION FILTER
2041 MAIN SURFACE
2043 OUTER PERIPHERAL SURFACE
205 RECEPTION CIRCUIT
206 LOW-NOISE AMPLIFIER
261 INPUT TERMINAL
262 OUTPUT TERMINAL
207 INPUT MATCHING CIRCUIT
208 MATCHING CIRCUIT
209 LOW PASS FILTER
210 CONTROLLER
300 COMMUNICATION DEVICE
301 SIGNAL PROCESSING CIRCUIT
302 RF SIGNAL PROCESSING CIRCUIT
303 BASEBAND SIGNAL PROCESSING CIRCUIT
310 ANTENNA
A4 CENTER
A5 CENTER
A6 CENTER
CA4 CENTER LINE
CA5 CENTER LINE
CA6 CENTER LINE
D0 THICKNESS DIRECTION
D1 FIRST DIRECTION
D2 SECOND DIRECTION
D3 THICKNESS DIRECTION
E203 AREA
E207 AREA
E208 AREA
H16 SHORTEST DISTANCE
H21 SHORTEST DISTANCE
H22 SHORTEST DISTANCE
H26 SHORTEST DISTANCE
H40 SHORTEST DISTANCE
H41 SHORTEST DISTANCE
H42 SHORTEST DISTANCE
H43 SHORTEST DISTANCE
H44 SHORTEST DISTANCE
H50 SHORTEST DISTANCE
H51 SHORTEST DISTANCE
H52 SHORTEST DISTANCE
H53 SHORTEST DISTANCE
H54 SHORTEST DISTANCE
H60 SHORTEST DISTANCE
H61 SHORTEST DISTANCE
H62 SHORTEST DISTANCE
H63 SHORTEST DISTANCE
H64 SHORTEST DISTANCE
Ru1 TRANSMISSION PATH
SL4 STRAIGHT LINE
SL5 STRAIGHT LINE
SL6 STRAIGHT LINE
T0 EXTERNAL CONNECTION TERMINAL
T1 ANTENNA TERMINAL
T2 SIGNAL INPUT TERMINAL
T4 SIGNAL OUTPUT TERMINAL
T3 EXTERNAL CONTROL TERMINAL
T5 EXTERNAL GROUND TERMINAL

1. An IC chip comprising:
a substrate;
a first switch unit provided at the substrate and including a first common terminal connected to an antenna terminal and a plurality of first selection terminals connectable to the first common terminal;
a second switch unit provided at the substrate and including a second common terminal connected to a transmission path and a plurality of second selection terminals connectable to the second common terminal;
a control unit provided at the substrate and connected to at least one of the first switch unit and the second switch unit;
a plurality of first terminals located between the first switch unit and the second switch unit in a first direction and arranged in a line in a second direction intersecting with the first direction, in plan view from a thickness direction of the substrate; and
a plurality of second terminals located between the plurality of first terminals, and the first switch unit or the second switch unit and arranged in a line in the second direction, in plan view from the thickness direction of the substrate,
wherein the plurality of first terminals include at least one control terminal among a plurality of control terminals connected to the control unit, and
the plurality of second terminals include a ground terminal.

2. The IC chip according to claim 1,
wherein the plurality of first terminals include all of the plurality of control terminals.

3. The IC chip according to claim 2,
wherein the plurality of first terminals further include a second ground terminal separate from a first ground terminal being the ground terminal.

4. The IC chip according to claim 1,
wherein the plurality of first terminals further include a second ground terminal separate from a first ground terminal being the ground terminal, and
the plurality of second terminals further include a control terminal not included in the plurality of first terminals among the plurality of control terminals.

5. The IC chip according to claim 1, further comprising:
a plurality of third terminals disposed between the first switch unit and the second switch unit in the first direction and arranged in a line in the second direction, in plan view from the thickness direction of the substrate,
wherein the plurality of third terminals include a ground terminal.

6. The IC chip according to claim 5,
wherein the plurality of first terminals are located between the plurality of second terminals and the plurality of third terminals in the first direction.

7. The IC chip according to claim 1,
wherein an outer edge of the IC chip includes
a first side and a second side facing each other in the first direction, and
a third side and a fourth side facing each other in the second direction, and
in plan view from the thickness direction of the substrate,
a shortest distance between a first terminal closest to the third side and a first terminal closest to the fourth side among the plurality of first terminals is longer than three-quarters of a shortest distance between the third side and the fourth side.

8. The IC chip according to claim 1,
wherein an outer edge of the IC chip includes
a first side and a second side facing each other in the first direction, and
a third side and a fourth side facing each other in the second direction, and
in plan view from the thickness direction of the substrate,
a shortest distance between one first terminal closest to the third side among the plurality of first terminals and the third side is shorter than a distance between the one first terminal closest to the third side and another first terminal adjacent to the one first terminal closest to the third side, and
a shortest distance between one first terminal closest to the fourth side among the plurality of first terminals and the fourth side is shorter than a distance between the one first terminal closest to the fourth side and another first terminal adjacent to the one first terminal closest to the fourth side.

9. The IC chip according to claim 1,
wherein the second common terminal is a terminal connected to the transmission path and connected to an output terminal of a power amplifier, and
the plurality of second selection terminals include terminals to which a plurality of transmission filters having pass bands different from each other are connected.

10. The IC chip according to claim 1,
wherein the second common terminal is a terminal connected to the transmission path and connected to an input terminal of a power amplifier, and
the plurality of second selection terminals include a plurality of terminals to which transmission signals different from each other are inputted.

11. A radio frequency module comprising:
the IC chip according to claim 1; and
a mounting board on which the IC chip is disposed.

12. The radio frequency module according to claim 11, further comprising:
a plurality of external connection terminals; and
a power amplifier connected to the transmission path,
wherein the mounting board has a first main surface and a second main surface facing each other,
the power amplifier is disposed on the first main surface of the mounting board,
the plurality of external connection terminals and the IC chip are disposed on the second main surface of the mounting board, and
in plan view from a thickness direction of the mounting board, a distance between the power amplifier and the second switch unit is shorter than a distance between the power amplifier and the first switch unit.

13. The radio frequency module according to claim 12, further comprising:
a low-noise amplifier disposed on the second main surface of the mounting board and connectable to at least one first selection terminal among the plurality of first selection terminals,
wherein, in plan view from the thickness direction of the mounting board, a shortest distance between the low-noise amplifier and the second switch unit is longer than a shortest distance between the low-noise amplifier and the first switch unit.

14. The radio frequency module according to claim 11, further comprising:
a plurality of transmission filters connected to the plurality of second selection terminals.

15. A communication device comprising:
the radio frequency module according to claim 11; and
a signal processing circuit connected to the radio frequency module.

16. The IC chip according to claim 2, further comprising:
a plurality of third terminals disposed between the first switch unit and the second switch unit in the first direction and arranged in a line in the second direction, in plan view from the thickness direction of the substrate,
wherein the plurality of third terminals include a ground terminal.

17. The IC chip according to claim 3, further comprising:
a plurality of third terminals disposed between the first switch unit and the second switch unit in the first direction and arranged in a line in the second direction, in plan view from the thickness direction of the substrate,
wherein the plurality of third terminals include a ground terminal.

18. The IC chip according to claim 4, further comprising:
a plurality of third terminals disposed between the first switch unit and the second switch unit in the first direction and arranged in a line in the second direction, in plan view from the thickness direction of the substrate,
wherein the plurality of third terminals include a ground terminal.

19. The IC chip according to claim 2,
wherein an outer edge of the IC chip includes
a first side and a second side facing each other in the first direction, and
a third side and a fourth side facing each other in the second direction, and
in plan view from the thickness direction of the substrate,
a shortest distance between a first terminal closest to the third side and a first terminal closest to the fourth side among the plurality of first terminals is longer than three-quarters of a shortest distance between the third side and the fourth side.

20. The IC chip according to claim 3,
wherein an outer edge of the IC chip includes
a first side and a second side facing each other in the first direction, and
a third side and a fourth side facing each other in the second direction, and
in plan view from the thickness direction of the substrate,
a shortest distance between a first terminal closest to the third side and a first terminal closest to the fourth side among the plurality of first terminals is longer than three-quarters of a shortest distance between the third side and the fourth side.
